(19) United States
(12) Patent Application Publication
(10) Pub. No.: US 2014/0117339 A1
(43) Pub. Date: May 1, 2014

(54) Light-Emitting Panel, Display Device, and Method for Manufacturing Light-Emitting Panel

(71) Applicant: Semiconductor Energy Laboratory Co., Ltd., Kanagawa-ken (JP)

(72) Inventor: Satoshi Seo, Sagamihara (JP)

(73) Assignee: Semiconductor Energy Laboratory Co., Ltd., Kanagawa-ken (JP)

(21) Appl. No.: 14/063,556

(22) Filed: Oct. 25, 2013

(30) Foreign Application Priority Data
Oct. 30, 2012 (JP) 2012-238679

(51) Int. Cl. H01L 51/52; H01L 51/56; H01L 27/32

(52) U.S. Cl. CPC H01L 51/52; H01L 27/3211; H01L 51/56
USPC 257/40; 257/89; 438/29

(57) ABSTRACT

A light-emitting panel in which a decrease in aperture ratio accompanied by fabrication of a high-definition panel is suppressed is provided. A light-emitting panel which can be produced easily is provided. The light-emitting panel includes a first light-emitting element and a second light-emitting element which include a selectively formed layer containing a light-emitting organic compound, optical elements which are formed before forming the layer or formed so as not to cause damage to the layer and which light emitted from the first light-emitting element or the second light-emitting element enters, and a third light-emitting element which does not include the selectively formed layer containing the light-emitting organic compound. Lights of different colors are emitted from the optical elements and the third light-emitting element.

### TECHNICAL FIELD

The present invention relates to a light-emitting panel, a display device including the light-emitting panel, and a method for manufacturing the light-emitting panel. In particular, the present invention relates to a light-emitting panel provided with a plurality of light-emitting modules that emit lights with different colors and a display device including the light-emitting panel.

### BACKGROUND ART

A light-emitting element, a light-emitting module in which an optical element such as a color filter, a color conversion layer, or a polarizing plate is provided to overlap with a light-emitting element, and a light-emitting panel in which a plurality of light-emitting elements or a plurality of light-emitting modules is provided in a matrix over a substrate are known.

A light-emitting element (also referred to as an organic EL element) which includes a pair of electrodes and a layer containing a light-emitting organic compound between the pair of electrodes is known. Features of the organic EL element are surface light emission and high-speed response to an input signal. Due to these features, an organic EL element is suitable for a light-emitting panel and a display device.

Further, performances such as high definition, high productivity, high reliability, and low power consumption are required for display devices.

For example, there is a method in which light-emitting layers for different emission colors are selectively fowled over a substrate using a shadow mask to form light-emitting elements for different emission colors. A light-emitting panel formed using this method does not need a color filter and thus is advantageous in reducing power consumption.

However, the step of selectively providing light-emitting layers of different emission colors by using a shadow mask has a problem in achieving high definition and high productivity of a display device.

Furthermore, a light-emitting panel in which a color filter overlaps with white-light-emitting elements and a light-emitting panel in which a color conversion layer overlaps with blue-light-emitting elements are known. These are advantageous in achieving high definition.

However, these light-emitting panels have a problem of energy loss by the color filter or the color conversion layer when pursuing low power consumption and high reliability.

In a step of selectively forming layers containing light-emitting organic compounds that emit light of different colors over a substrate, actual positions where the layers containing the light-emitting organic compounds are formed are somewhat shifted from the desired positions.

For example, in the case of selectively forming layers containing light-emitting organic compounds by an evaporation method using a shadow mask, opening portions of the shadow mask are placed (aligned) at desired positions. At this time, if the shadow mask is misaligned, the layers containing the light-emitting organic compounds are formed at positions off the desired positions. As a result, for example, an adjacent light-emitting element may include a layer containing a light-emitting organic compound for an emission color that is different from the intended emission color, which may lower yield in manufacturing light-emitting panels.

As a method for selectively forming layers containing light-emitting organic compounds over a substrate, there is a droplet discharge method (ink-jet method) or the like in addition to the shadow mask method. However, either method has not a low possibility that the layers containing the light-emitting organic compounds would be formed at positions off the desired positions.

Allowing for misalignment, A sidewall is provided between light-emitting elements for different emission colors to form a space therebetween.

Note that the size of the space (the length of the space) is determined depending on the method for selectively forming layers containing light-emitting organic compounds and the accuracy of apparatus.

### REFERENCE

### Patent Document

[Patent Document 1] Japanese Published Patent Application No. 2005-129509
[Patent Document 2] Japanese Published Patent Application No. 2010-165510

### DISCLOSURE OF INVENTION

High definition of a light-emitting panel is expected.

As a light-emitting panel has higher definition, the distance between light-emitting elements becomes shorter naturally.

By shortening the breadth of light-emitting elements as well as providing a space between the light-emitting elements, the aperture ratio of the light-emitting elements becomes lower. If the light-emitting elements are driven at high current density in order to compensate for the reduction in luminance caused by the low aperture ratio, the reliability of the light-emitting elements may be degraded in some cases.

One embodiment of the present invention is made in view of the foregoing technical background. It is an object of one embodiment of the present invention to provide a novel light-emitting panel. Further, it is another object to provide a method for manufacturing a novel light-emitting panel.

An embodiment of the present invention is a light-emitting panel which includes a first sub-pixel including a first light-emitting element in which an island-shaped first layer containing a light-emitting organic compound is provided between a pair of electrodes and a first optical element overlapping with the first light-emitting element, and configured to emit light with a first color; a second sub-pixel including a second light-emitting element in which the island-shaped first layer is provided between a pair of electrodes and a second optical element overlapping with the second light-emitting element, and configured to emit light with a second color; and a third sub-pixel including a third light-emitting element in which a second layer containing a light-emitting organic compound is provided between a pair of electrodes, configured to emit light with a third color, and provided apart from the first sub-pixel and the second sub-pixel. In the light-emitting panel, a length of a space between the first light-emitting element and the second light-emitting element is smaller than a length of a space between the first light-emitting element and the third light-emitting element and smaller than a length of a space between the second light-emitting element and the third light-emitting element.

Another embodiment of the present invention is a light-emitting panel which includes a first sub-pixel including a first light-emitting element in which an island-shaped first layer having a long axis and a short axis intersecting with the long axis and containing a light-emitting organic compound is provided between a pair of electrodes and a first optical element selectively transmitting light with a first color of light emitted from the first light-emitting element; a second sub-pixel including a second light-emitting element in which the island-shaped first layer is provided between a pair of electrodes and a second optical element selectively transmitting light with a second color of light emitted from the second light-emitting element; and a third sub-pixel including a third light-emitting element in which a second layer containing a light-emitting organic compound is provided between a pair of electrodes, configured to emit light with a third color, and provided apart from the first sub-pixel and the second sub-pixel. In the light-emitting panel, the first light-emitting element and the second light-emitting element are aligned in a direction along the long axis, and a length of a space between the first light-emitting element and the second light-emitting element in the direction along the long axis is smaller than a length of a space between the first light-emitting element and the third light-emitting element in a direction along the short axis and smaller than a length of a space between the second light-emitting element and the third light-emitting element in the direction along the short axis.

Another embodiment of the present invention is the light-emitting panel having the above-described structure, in which a sum of a length of the first light-emitting element, a length of the second light-emitting element, and the length of the space between the first light-emitting element and the second light-emitting element in the direction along the long axis of the island-shaped first layer containing the light-emitting organic compound is larger than a length of the first light-emitting element in the direction along the short axis and larger than a length of the second light-emitting element in the direction along the short axis.

Another embodiment of the present invention is the light-emitting panel having the above-described structure, in which each of the first light-emitting element, the second light-emitting element, and the third light-emitting element includes the second layer containing the light-emitting organic compound between the pair of electrodes; in which each of the first light-emitting element and the second light-emitting element includes the island-shaped first layer containing the light-emitting organic compound between the second layer and the electrode functioning as an anode of the pair of electrodes; in which the island-shaped first layer contains a plurality of light-emitting organic compounds so as to emit light with the first color and light with the second color; and in which the second layer contains a light-emitting organic compound that emits light with the third color.

Another embodiment of the present invention is the light-emitting panel having the above-described structure, in which each of the first light-emitting element, the second light-emitting element, and the third light-emitting element includes the second layer containing the light-emitting organic compound between the pair of electrodes; in which each of the first light-emitting element and the second light-emitting element includes the island-shaped first layer containing the light-emitting organic compound between the second layer and the electrode functioning as an anode of the pair of electrodes; in which the island-shaped first layer contains a plurality of light-emitting organic compounds so as to emit light with the first color and light with the second color; in which the second layer contains a light-emitting organic compound that emits light with the third color; in which the first light-emitting element includes a first optical distance adjustment layer and a reflective film and a semitransparent/semireflective film which is provided so as to preferentially extract light with the first color, as a first optical element; and in which the second light-emitting element includes a second optical distance adjustment layer and a reflective film and a semitransparent/semireflective film which is provided so as to preferentially extract light with the second color, as a second optical element.

Another embodiment of the present invention is a display device including the light-emitting panel of any of the above embodiments.

Another embodiment of the present invention is a method for manufacturing a light-emitting panel, which includes a first step of, by a photolithography method, forming a first lower electrode in which a first optical distance adjustment layer is stacked over a first reflective layer over a substrate having an insulating surface, forming a second lower electrode in which a second optical distance adjustment layer is stacked over a second reflective layer over the substrate with a first space provided between the first lower electrode and the second lower electrode, and forming a third lower electrode over a third reflective layer over the substrate with a second space having a length larger than a length of the first space provided between the third lower electrode and the first lower electrode and between the third lower electrode and the second lower electrode; a second step of forming an island-shaped first layer containing a light-emitting organic compound by a shadow mask method over the first lower electrode and the second lower electrode; a third step of forming a second layer containing a light-emitting organic compound over the island-shaped first layer and the third lower electrode so that the second layer overlaps with the first lower electrode and the second lower electrode; and a fourth step of forming a upper electrode over the second layer so that the upper electrode overlaps with the first lower electrode, the second lower electrode, and the third lower electrode.

Note that in this specification, an “EL layer” refers to a layer provided between a pair of electrodes in a light-emitting element. Thus, a light-emitting layer containing an organic compound that is a light-emitting substance which is interposed between electrodes is one embodiment of the EL layer.

In this specification, in the case where a substance A is dispersed in a matrix formed using a substance B, the substance B forming the matrix is referred to as a host material, and the substance A dispersed in the matrix is referred to as a guest material. Note that the substance A and the substance B may each be a single substance or a mixture of two or more kinds of substances.

Note that a display device in this specification means an image display device, a light-emitting device, or a light source (including a lighting device). In addition, the display device includes any of the following modules in its category: a module in which a connector such as a flexible printed circuit (FPC) or a tape carrier package (TCP) is attached to a display device; a module having a TCP provided with a printed wiring board at the end thereof; and a module having an integrated circuit (IC) directly mounted over a substrate over which a light-emitting element is formed by a chip on glass (COG) method.

With one embodiment of the present invention, a novel light-emitting panel can be provided. Further, a method for manufacturing a novel light-emitting panel can be provided.

### BRIEF DESCRIPTION OF DRAWINGS

In the accompanying drawings:

FIGS. 1A and 1B illustrate a structure of a light-emitting panel of an embodiment;

FIGS. 2A and 2B illustrate a structure of a light-emitting panel of an embodiment;

FIG. 3 illustrates a structure of a light-emitting panel of an embodiment;

FIGS. 4A and 4B illustrate a structure of a light-emitting panel of an embodiment;

FIGS. 5A and 5B illustrate a structure of a light-emitting panel of an embodiment;

FIGS. 6A to 6D illustrate a method for manufacturing a light-emitting panel of an embodiment;

FIGS. 7A to 7C illustrate a method for manufacturing a light-emitting panel of an embodiment;

FIGS. 8A1, 8A2, 8B1 and 8B2 illustrate the relationship between misalignment and the layout of light-emitting elements in sub-pixels and a space between the light-emitting elements in a light-emitting panel of an embodiment;

FIGS. 9A1, 9A2, 9B1, and 9B2 illustrate the layout of light-emitting elements in sub-pixels and a space between the light-emitting elements in a light-emitting panel of an embodiment;

FIGS. 10A, 10B1, and 10B2 are schematic views of structures of light-emitting elements of an embodiment;

FIGS. 11A and 11B illustrate a structure of a display panel of an embodiment; and

FIGS. 12A to 12C illustrate a method for manufacturing a display panel of an embodiment.

### BEST MODE FOR CARRYING OUT THE INVENTION

Embodiments will be described in detail with reference to the drawings. The present invention is not limited to the following description, and it will be easily understood by those skilled in the art that various changes and modifications can be made without departing from the spirit and scope of the present invention. Therefore, the present invention should not be construed as being limited to the description in the embodiments described below. Note that in the structures of the invention described below, the same portions or portions having similar functions are denoted by the same reference numerals in different drawings, and description of such portions is not repeated.

### Embodiment 1

An object of one embodiment of the present invention is to provide a novel light-emitting panel in which a decrease in aperture ratio accompanied by fabrication of a high-definition panel is prevented.

In a manufacturing process of a light-emitting panel, there is a possibility that misalignment may occur. In the case of providing a space in a light-emitting panel allowing for the misalignment, the following points should be noted.

First, a large space is necessary to allow for misalignment as compared to the other technology for selectively forming thin films (e.g., photolithography, nanoimprint lithography), in a step of selectively forming layers containing light-emitting organic compounds.

Second, as the number of layers containing light-emitting organic compounds, which are formed selectively, increases, the space for allowing misalignment needs to be larger.

Third, a step that may cause damage to the layers containing light-emitting organic compounds is involved in most of micromachining technologies which cause less severe misalignment compared to the step of selectively forming layers containing light-emitting organic compounds.

One embodiment of the present invention has been made focusing on the space for the misalignment caused in the step of manufacturing a light-emitting panel. Thus, a light-emitting panel with a structure exemplified in this specification has been devised.

Specifically, the devised structure includes a plurality of light-emitting elements which share one selectively formed layer containing a light-emitting organic compound, a light-emitting element which does include the layer containing the light-emitting organic compound, and optical elements each fabricated more finely than the layer containing the light-emitting organic compound. These light-emitting elements are arranged with a space required for the step of selectively forming layers containing light-emitting organic compounds and a space smaller than the space required for the step therebetween.

One embodiment of the present invention is a light-emitting panel which includes a first light-emitting element and a second light-emitting element which include a selectively formed layer containing a light-emitting organic compound, optical elements which are formed before formation of the layer containing the light-emitting organic compound or formed so as not to cause damage to the layer containing the light-emitting organic compound and which light emitted from the first light-emitting element or the second light-emitting element enters, and a third light-emitting element which does not include the selectively formed layer containing the light-emitting organic compound. Lights with different colors are emitted from the optical elements and the third light-emitting element. The length of a space provided between the first and third light-emitting elements and the length of a space provided between the second and third light-emitting elements are each larger than the length of a space provided between the first and second light-emitting elements.

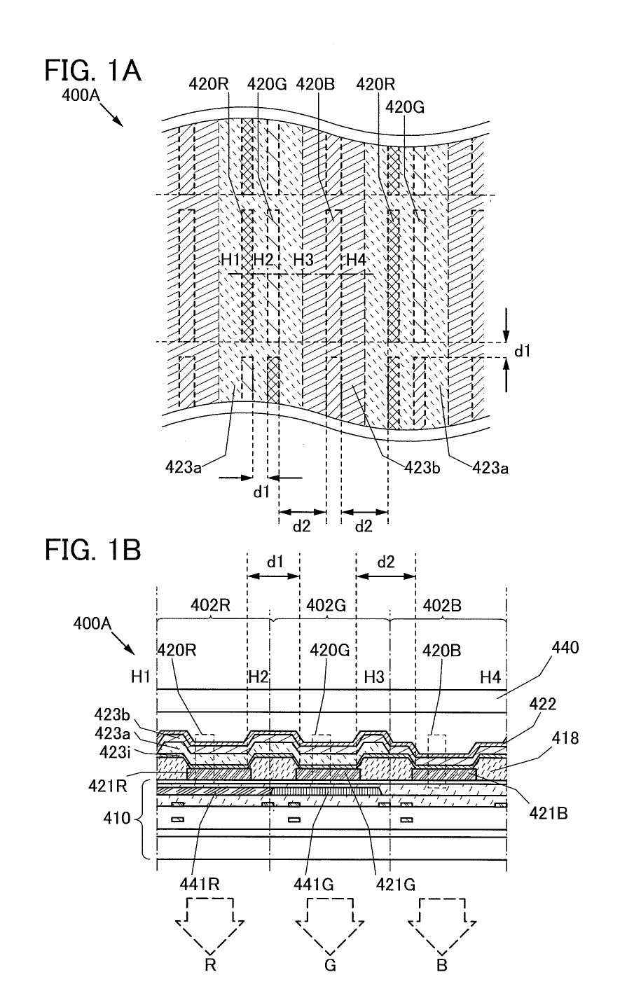

In this embodiment, a structure of the light-emitting panel of one embodiment of the present invention will be described with reference to FIGS. 1A and 1B.

FIG. 1A is a top view of the structure of a light-emitting panel 400A of one embodiment of the present invention, and FIG. 1B is a side view of the structure of the light-emitting panel 400A along line H1-H2-H3-H4 in FIG. 1A.

The light-emitting panel 400A described in this embodiment as an example includes a first sub-pixel 402R, a second sub-pixel 402G; and a third sub-pixel 402B over a substrate 410.

The first sub-pixel 402R includes a first light-emitting element 420R in which an island-shaped first layer 423a containing a light-emitting organic compound is sandwiched between a pair of electrodes (a first lower electrode 421R and an upper electrode 422), and a first optical element 441R overlapping with the first light-emitting element 420R, and emits light with a first color.

The second sub-pixel 402G includes a second light-emitting element 420G in which the island-shaped first layer 423a containing the light-emitting organic compound is sandwiched between a pair of electrodes (a second lower electrode 421G and the upper electrode 422), and a second optical element 441G overlapping with the second light-emitting element 420Q and emits light with a second color.

The third sub-pixel 402B includes a third light-emitting element 420B in which a second layer 423b containing a light-emitting organic compound is sandwiched between a pair of electrodes (a third lower electrode 421B and the upper electrode 422), emits light with a third color, and is positioned apart from the first sub-pixel 402R and the second sub-pixel 402G

A length d1 of a space provided between the first light-emitting element 420R and the second light-emitting element 420G is smaller than a length d2 of a space provided between the first light-emitting element 420R and the third light-emitting element 420B and smaller than a length d2 of a space provided between the second light-emitting element 420G and the third light-emitting element 420B.

Note that in this specification, the term “island-shaped” is used to refer to the state of a region isolated by patterning. For example, a layer formed over a substrate is patterned into an island shape along the perimeter of the substrate or a region of an element. Specifically, in the case of patterning a film by a shadow mask method, the film is patterned into an island shape having substantially the same shape as an opening portion of the shadow mask. A film is patterned into stripes in some cases. Further, the term “the length of a space” refers to the shortest distance between two lower electrodes.

The light-emitting panel 400A described in this embodiment as an example has a bottom-emission structure, where lights emitted from the light-emitting elements are extracted from the substrate side on which the light-emitting elements are formed. The substrate 410 is provided with the first optical element 441R and the second optical element 441G. Note that one embodiment of the present invention may have, other than the bottom-emission structure, a top-emission structure where lights emitted from the light-emitting elements are extracted from the side opposite to the substrate 410 over which the light-emitting elements are formed. In the case of the top-emission structure, the upper electrode 422 is formed from a light-transmitting conductive film, and a counter substrate 440 is provided with the first optical element 441R and the second optical element 441G

By forming the lower electrodes (the first lower electrode 421R, the second lower electrode 421G and the third lower electrode 421B) from a light-transmitting conductive film, light emitted from any of the light-emitting elements (the first light-emitting element 420R, the second light-emitting element 420G and the third light-emitting element 420B) is extracted from the substrate 410 side. Accordingly, light emitted from the first light-emitting element 420R and light emitted from the second light-emitting element 420G are extracted from the substrate 410 side through the first optical element 441R and the second optical element 441G, respectively. Light emitted from the third light-emitting element 420B is directly extracted from the substrate 410 side.

In this manner in one embodiment of the present invention, an optical element is not necessary for the third light-emitting element, and light emitted from the third light-emitting element can be extracted directly. For this reason, one embodiment of the present invention has an advantage in power consumption and lifetime over a light-emitting panel in which a color filter overlaps with a white-light-emitting element or a light-emitting panel in which a color conversion layer overlaps with a blue-light-emitting element. In the case of using a blue fluorescent light-emitting element as the third light-emitting element, the effect of reducing power consumption is significant. Note that in the case of not providing an optical element for the third light-emitting element, a circularly polarizing plate is preferably provided depending on the usage in order to prevent reflection of external light in the third light-emitting element.

The light-emitting panel 400A includes an insulating sidewall 418. The sidewall 418 covers edges of the lower electrodes (the first lower electrode 421R, the second lower electrode 421G. In addition, the sidewall 418 has a plurality of opening portions. The first lower electrode 421R, the second lower electrode 4216, and the third lower electrode 421B are exposed at the opening portions.

The light-emitting panel 400A includes a layer 423i containing an organic compound. The layer 423i containing an organic compound is in contact with the lower electrodes (the first lower electrode 421R, the second lower electrode 421G, and the third lower electrode 421B).

In the light-emitting panel 400A described in this embodiment as an example, the first light-emitting element 420R and the second light-emitting element 420G each include the island-shaped first layer 423a containing the light-emitting organic compound, while the third light-emitting element 420B includes the second layer 423b containing the light-emitting organic compound. In addition, the first optical element 441R overlapping with the first light-emitting element 420R and the second optical element 441G overlapping with the second light-emitting element 420G are included. The length d1 of the space provided between the first light-emitting element 420R and the second light-emitting element 420G is smaller than the length d2 of the space provided between the first light-emitting element 420R and the third light-emitting element 420B and smaller than the length d2 of the space provided between the second light-emitting element 420G and the third light-emitting element 420B.

With this structure, it is not necessary to provide, between the first light-emitting element 420R and the second light-emitting element 420G, a space for misalignment that may be caused at the time of selectively forming the island-shaped first layer 423a containing the light-emitting organic compound. Therefore, the length d1 of the space provided between the first light-emitting element 420R and the second light-emitting element 420G can be set small.

Note that it is necessary to prevent the island-shaped first layer 423a containing the light-emitting organic compound from overlapping with the third light-emitting element 420B owing to the misalignment caused at the time of selectively forming the island-shaped first layer 423a containing the light-emitting organic compound. Specifically, the space for misalignment needs to be provided between the first light-emitting element 420R and the third light-emitting element 420B and between the second light-emitting element 420G and the third light-emitting element 420B. That is, the length d2 in the short-axis direction of the space needs to be large enough.

In other words, the length d1 of the space provided between the first light-emitting element 420R and the second light-emitting element 420G can be set smaller than the length d2 of the space provided between the first light-emitting element 420R and the third light-emitting element 420B and smaller than the length d2 of the space provided between the second light-emitting element 420G and the third light-emitting element 420B. Consequently, it is possible to provide the novel light-emitting panel 400A in which a decrease in aperture ratio accompanied by fabrication of a high-definition panel is prevented.

The following describes individual components constituting the light-emitting panel of one embodiment of the present invention.

### <Light-Emitting Panel>

The light-emitting panel 400A includes a plurality of sub-pixels. Note that a plurality of sub-pixels may form one pixel.

By selectively driving the sub-pixels, the emission color and the luminance of the light-emitting panel can be adjusted. In addition, a pattern, an image, or information can be displayed with colors on the light-emitting panel, and furthermore, the intensity and color of light emitted from the light-emitting panel and the distribution of the light intensity and color can be controlled.

### <Substrate>

The substrate 410 has a light-transmitting property in a region overlapping with the light-emitting elements (the first light-emitting element 420R, the second light-emitting element 420G, and the third light-emitting element 420B). Note that the substrate 410 can be provided with a variety of electronic elements such as a wiring for supplying power to the lower electrodes (the first lower electrode 421R, the second lower electrode 421G, and the third lower electrode 421B) of the light-emitting elements, a switching element (e.g., a transistor), and a signal line for controlling a switching element.

### <Sub-Pixel>

The sub-pixels (the first sub-pixel 402R, the second sub-pixel 402G, and the third sub-pixel 402B) emit different colors. For example, the first sub-pixel 402R emits light with red color, the second sub-pixel 402G emits light with green color, and the third sub-pixel 402B emits light with blue color.

With this structure, a white-light-emitting panel can be provided. Further, a light-emitting panel for full-color display devices can be provided.

### <Light-Emitting Element>

In each of the light-emitting elements (the first light-emitting element 420R, the second light-emitting element 420G, and the third light-emitting element 420B), a layer containing a light-emitting organic compound is sandwiched between a pair of electrodes (specifically, the lower electrode and the upper electrode 422).

The lower electrodes (the first lower electrode 421R, the second lower electrode 421G, and the third lower electrode 421B) are each formed over the substrate 410. The lower electrodes are electrically connected to wirings (not shown), and different potentials can be supplied to the lower electrodes.

In contrast, the upper electrode 422 is formed of one conductive film, and a common potential is supplied to the light-emitting elements.

With this structure, the first light-emitting element 420R, the second light-emitting element 420G, and the third light-emitting element 420B can be driven selectively.

Note that each of the first lower electrode 421R, the second lower electrode 421G, and the third lower electrode 421B of the light-emitting panel 400A is formed of a light-transmitting conductive film. In addition, the upper electrode 422 is formed of a reflective conductive film.

### <Structures of First Light-Emitting Element and Second Light-Emitting Element>

The first light-emitting element and the second light-emitting element each include at least the island-shaped first layer 423a containing the light-emitting organic compound between the pair of electrodes. Further, they may also include the second layer 423b containing the light-emitting organic compound between the pair of electrodes. Here, the case in which both the island-shaped first layer 423a containing the light-emitting organic compound and the second layer 423b containing the light-emitting organic compound are included between the pair of electrodes is described.

The island-shaped first layer 423a containing the light-emitting organic compound contains a light-emitting organic compound and emits light by current flowing between the pair of electrodes.

Carriers injected from the lower electrode and carriers injected from the upper electrode are recombined in the island-shaped first layer 423a containing the light-emitting organic compound. In this way, the carriers injected from the lower electrode and the carriers injected from the upper electrode are prevented from reaching the upper electrode and the lower electrode, respectively, and causing a flow of current without contributing to light emission. Consequently, a current can be converted into light efficiently.

The island-shaped first layer 423a containing the light-emitting organic compound described in this embodiment as an example contains an organic compound that emits light with red color and an organic compound that emits light with green color, and emits light with red color and light with green color when power is supplied to the pair of electrodes (the lower electrode and the upper electrode).

Further, the second layer 423b containing the light-emitting organic compound transports carriers injected from the upper electrode 422 to the island-shaped first layer 423a containing the light-emitting organic compound.

Note that the layer 423i containing the organic compound may be provided between the lower electrode and the island-shaped first layer 423a containing the light-emitting organic compound so as to be in contact with the lower electrode. The layer 423i containing the organic compound can serve as a carrier injection layer, for example. By providing the carrier injection layer in contact with the lower electrode, injection of carriers from the lower electrode is facilitated and driving voltage of the light-emitting element can be reduced.

### <Structure of Third Light-Emitting Element>

The third light-emitting element includes the second layer 423b containing the light-emitting organic compound between the pair of electrodes and does not include the island-shaped first layer 423a containing the light-emitting organic compound.

The second layer 423b containing the light-emitting organic compound emits light when power is supplied to the pair of electrodes. The light emitted from the second layer 423b containing the light-emitting organic compound has a color different from the color emitted from the island-shaped first layer 423a containing the light-emitting organic compound.

Furthermore, carriers injected from the lower electrode and carriers injected from the upper electrode are recombined in the second layer containing the light-emitting organic compound. In this way, the carriers injected from the lower electrode and the carriers injected from the upper electrode are prevented from reaching the upper electrode and the lower electrode, respectively, and causing a flow of current without contributing to light emission. Consequently, a current can be converted into light efficiently.

The second layer 423b containing the light-emitting organic compound described in this embodiment as an example contains an organic compound that emits light with blue color, and emits light with blue color when power is supplied to the pair of electrodes.

### <Optical Element>

The first optical element 441R and the second optical element 441G selectively transmit light with a particular color out of incident light. For example, a color filter, a band pass filter, a multilayer filter, or the like can be used, for example.

The first optical element 441R described as an example transmits light with red color out of light emitted from the first light-emitting element 420R. The second optical element 441G transmits light with green color out of light emitted from the second light-emitting element 420G.

Alternatively, color conversion elements can be used as the optical elements. A color conversion element is an optical element that converts incident light into light having a longer wavelength than the incident light.

Note that the optical element may be provided so as to overlap with the third light-emitting element 420B, or a plurality of optical elements may be provided so as to overlap with the first light-emitting element 420R and/or the second light-emitting element 420G. As another optical element, a circularly polarizing plate, an anti-reflective film, or the like can be provided, for example. A circularly polarizing plate provided on the side where light emitted from the light-emitting element of the light-emitting panel is extracted can prevent a phenomenon in which light entering from the outside of the panel is reflected in the light-emitting panel and returned to the outside. An anti-reflective film can weaken external light reflected by a surface of the light-emitting panel. Accordingly, light emitted from the light-emitting panel can be observed clearly.

### <Space>

A space separates lower electrodes of a plurality of light-emitting elements. Separation of the lower electrodes by the space allows sub-pixels to be driven selectively.

In addition, the space is provided allowing for misalignment caused in the step of manufacturing a light-emitting panel. The space has a size more than the size required for the step of forming the lower electrodes so that the lower electrodes are separate from one another.

The first lower electrode 421R, the layer containing the light-emitting organic compound, and the upper electrode included in the first light-emitting element 420R are formed in the same steps as the second lower electrode 421G, the first layer 423a containing the light-emitting organic compound, and the upper electrode included in the second light-emitting element 420G. Misalignment does not occur among the components formed in the same step.

Thus, the length of the space provided between the first light-emitting element 420R and the second light-emitting element 420G can be the length of the space that is required at the time of forming the first lower electrode 421R and the second lower electrode 421G.

For example, in the case of forming the first lower electrode 421R and the second lower electrode 421G by photolithography, the space provided between the lower electrodes can be more than or equal to 2 μm and less than 20 μm although it depends on which photomask, exposure apparatus, and material are used.

In contrast, the third light-emitting element 420B does not include the island-shaped first layer 423a containing the light-emitting organic compound; in this point, the structure of the third light-emitting element 420B is different from those of the first light-emitting element 420R and the second light-emitting element 420G.

Therefore, the space for the misalignment caused at the step of selectively forming the island-shaped first layer 423a containing the light-emitting organic compound is provided between the first light-emitting element 420R and the third light-emitting element 420B and between the second light-emitting element 420G and the third light-emitting element 420B.

For example, in the case of selectively forming the island-shaped first layer 423a containing the light-emitting organic compound by an evaporation method using a shadow mask method, the length of the space can be about more than or equal to 20 μm and less than or equal to 100 μm although it depends on the accuracy of the evaporation apparatus and the shadow mask.

Note that the insulating sidewall 418 is provided in the space and covers edges of the lower electrodes. In addition, the sidewall 418 has a plurality of opening portions. The first lower electrode 421R, the second lower electrode 421G, and the third lower electrode 421B are exposed at the opening portions.

An organic material as well as an inorganic material can be used as the sidewall 418 as long as the sidewall 418 has an insulating property. For example, an acrylic resin, polyimide, a photosensitive resin, or the like can be used.

### <Counter Substrate>

The counter substrate 440 is bonded to the substrate 410 with a sealant (not shown). The sealant is provided to surround the first light-emitting element 420R, the second light-emitting element 420G, and the third light-emitting element 420B. With this structure, the first light-emitting element 420R, the second light-emitting element 420G, and the third light-emitting element 420B are sealed between the counter substrate 440 and the substrate 410.

Note that this embodiment can be implemented in appropriate combination with any of the other embodiments described in this specification.

### Embodiment 2

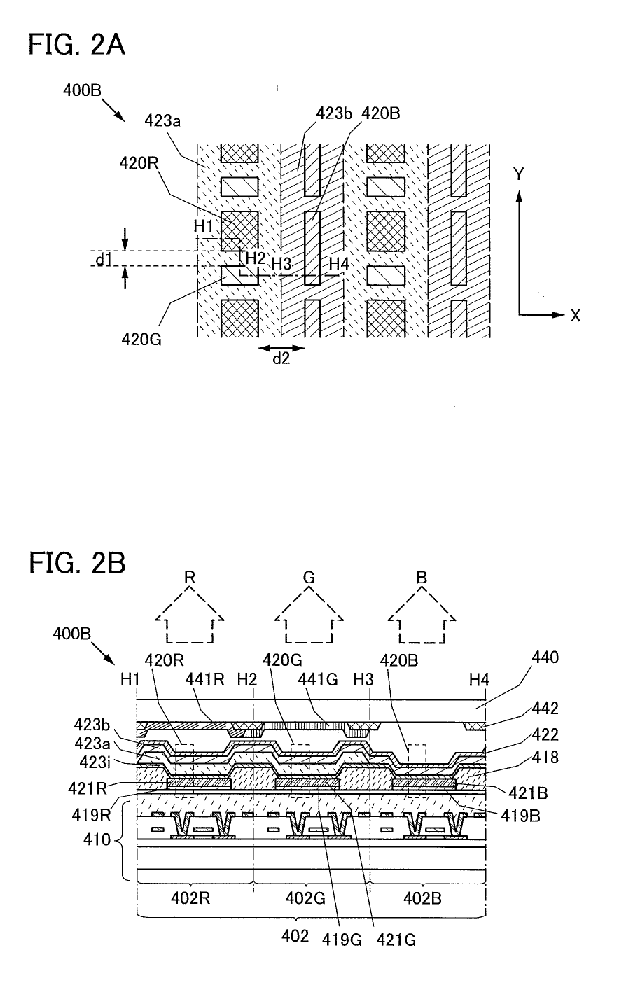

In this embodiment, structures of a light-emitting panel of one embodiment of the present invention will be described with reference to FIGS. 2A and 2B, FIG. 3, and FIGS. 8A1, 8A2, 8B1, and 8B2.

FIG. 2A is a top view of a structure of the light-emitting panel of one embodiment of the present invention, and FIG. 2B is a side view of the structure of the light-emitting panel along line H1-H2-H3-H4 in FIG. 2A.

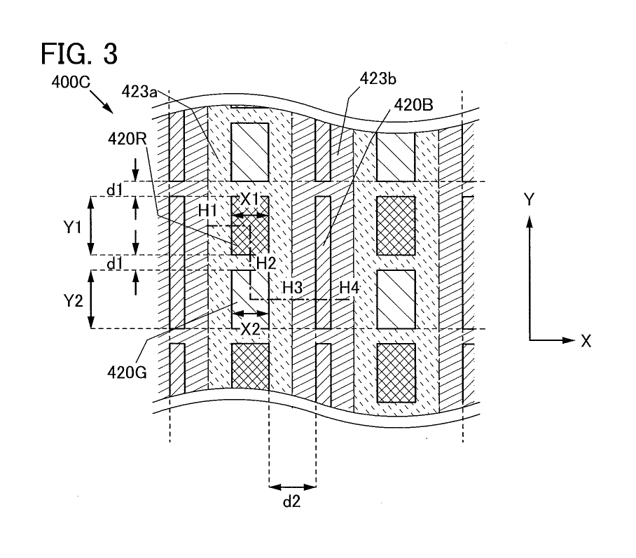

FIG. 3 is a top view of a structure of the light-emitting panel of one embodiment of the present invention.

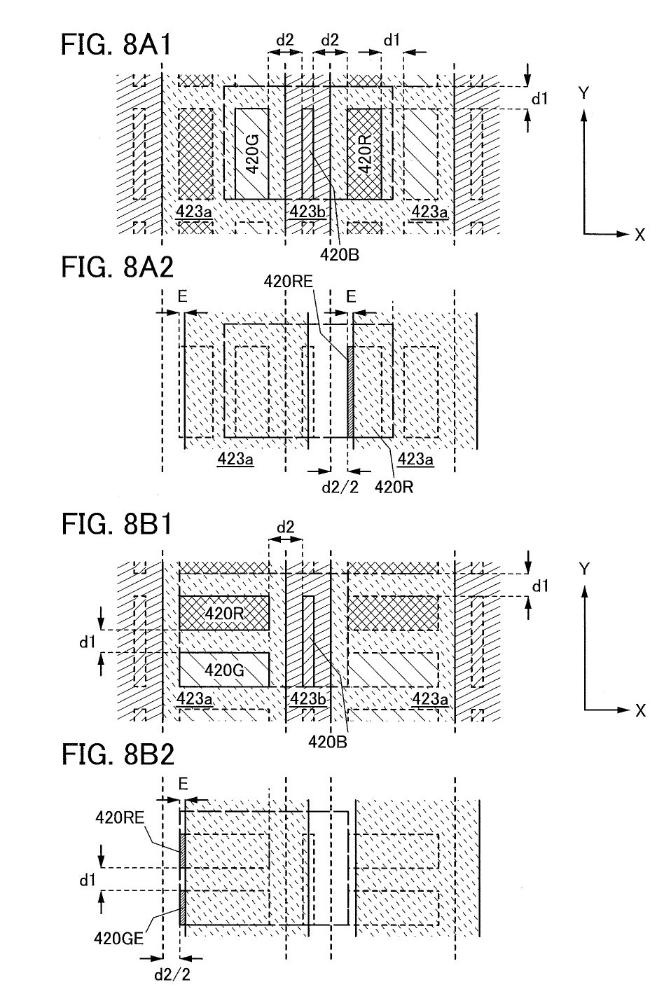

FIGS. 8A1, 8A2, 8B 1, and 8B2 are top views for describing the relationship between misalignment and the layout of light-emitting elements in sub-pixels and a space between the light-emitting elements in a light-emitting panel.

In a light-emitting panel 400B described in this embodiment as an example, a first sub-pixel 402R, a second sub-pixel 402G and a third sub-pixel 402B are included over a substrate 410.

The first sub-pixel 402R includes a first light-emitting element 420R in which an island-shaped first layer 423a containing a light-emitting organic compound and having a long axis (in the direction indicated by the arrow Y on the right side of the drawing) and a short axis that intersects with the long axis (in the direction indicated by the arrow X on the right side of the drawing. In this embodiment, the long axis Y is perpendicular to the short axis X.) is sandwiched between a pair of electrodes (a first lower electrode 421R and an upper electrode 422) and a first optical element 441R overlapping with the first light-emitting element 420R and selectively transmitting light with a first color of light emitted from the first light-emitting element 420R.

The second sub-pixel 402G includes a second light-emitting element 420G in which the island-shaped first layer 423a containing the light-emitting organic compound is sandwiched between a pair of electrodes (a second lower electrode 421G and the upper electrode 422), and a second optical element 441G overlapping with the second light-emitting element 420G and selectively transmitting light with a second color of light emitted from the second light-emitting element 420G.

The third sub-pixel 402B includes a third light-emitting element 420B in which a second layer 423b containing a light-emitting organic compound is sandwiched between a pair of electrodes (a third lower electrode 421B and the upper electrode 422), emits light with a third color, and is provided apart from the first sub-pixel 402R and the second sub-pixel 402G.

Further, the first light-emitting element 420R and the second light-emitting element 420G are arranged in the long-axis Y direction. A length d1 in the long-axis Y direction of a space provided between the first light-emitting element 420R and the second light-emitting element 420G is smaller than a length d2 in the short-axis X direction of a space provided between the first light-emitting element 420R and the third light-emitting element 420B or a space provided between the second light-emitting element 420G and the third light-emitting element 420B.

The light-emitting panel 400B described in this embodiment as an example has a top-emission structure, where lights are extracted from the side opposite to the substrate 410 (the substrate over which the light-emitting elements are formed) side. The upper electrode 422 is formed from a light-transmitting conductive film A counter substrate 440 is provided with the first optical element 441R and the second optical element 441G. Note that one embodiment of the present invention may have, other than the top-emission structure, a bottom-emission structure where lights emitted from the light-emitting elements are extracted from the substrate 410 side on which the light-emitting elements that emit lights are formed. In the case of the bottom-emission structure, the lower electrodes are formed from a light-transmitting conductive film, and the substrate 410 is provided with the first optical element 441R and the second optical element 441G.

The light-emitting panel 400B includes the counter substrate 440. The counter substrate 440 is provided with the first optical element 441R and the second optical element 441G. The first optical element 441R is provided at a position overlapping with the first light-emitting element 420R, and the second optical element 441G is provided at a position overlapping with the second light-emitting element 420G.

The counter substrate 440 is bonded to the substrate 410 with a sealant (not shown). The sealant is provided to surround the first light-emitting element 420R, the second light-emitting element 420G, and the third light-emitting element 420B. With this structure, the first light-emitting element 420R, the second light-emitting element 420G and the third light-emitting element 420B are sealed between the counter substrate 440 and the substrate 410.

The light-emitting panel 400B includes an insulating sidewall 418 covering edges of the lower electrodes (the first lower electrode 421R, the second lower electrode 4210, and the third lower electrode 421B). In addition, the sidewall 418 has a plurality of opening portions. The first lower electrode 421R, the second lower electrode 421G, and the third lower electrode 421B are exposed at the opening portions.

The light-emitting panel 400B includes a layer 423i containing an organic compound. The layer 423i containing the organic compound is in contact with the lower electrodes (the first lower electrode 421R, the second lower electrode 421G, and the third lower electrode 421B).

In the light-emitting panel 400B described in this embodiment as an example, the first light-emitting element 420R and the second light-emitting element 420G each include the island-shaped first layer 423a containing the light-emitting organic compound and having the long axis Y and the short axis X, while the third light-emitting element 420B includes the second layer 423b containing the light-emitting organic compound. In addition, the first optical element 441R and the second optical element 441G are included. The first optical element 441R overlaps with the first light-emitting element 420R, and the second optical element 441G overlaps with the second light-emitting element 420G.

Further, the first light-emitting element 420R and the second light-emitting element 420G are arranged in the long-axis Y direction. In addition, the length d1 in the long-axis Y direction of the space provided between the first light-emitting element 420R and the second light-emitting element 420G is smaller than the length d2 in the short-axis X direction of the space provided between the first light-emitting element 420R and the third light-emitting element 420B or the space provided between the second light-emitting element 420G and the third light-emitting element 420B.

With this structure, it is not necessary to provide, between the first light-emitting element 420R and the second light-emitting element 420G a space for misalignment that may be caused at the time of selectively forming the island-shaped first layer 423a containing the light-emitting organic compound. Therefore, the length d1 in the long-axis Y direction of the space provided between the first light-emitting element 420R and the second light-emitting element 420G can be set small.

Note that it is necessary to prevent the first layer 423a containing the light-emitting organic compound from overlapping with the third light-emitting element 420B owing to the misalignment caused at the time of selectively forming the first layer 423a containing the light-emitting organic compound. Specifically, the space for misalignment needs to be provided between the first light-emitting element 420R and the third light-emitting element 420B and between the second light-emitting element 420G and the third light-emitting element 420B. That is, the length d2 in the short-axis X direction of the space needs to be large enough to assure yield in the process.

In other words, the length d1 of the space provided between the first light-emitting element 420R and the second light-emitting element 420G can be set smaller than the length d2 of the space provided between the first light-emitting element 420R and the third light-emitting element 420B or the space provided between the second light-emitting element 420G and the third light-emitting element 420B. Consequently, it is possible to provide the novel light-emitting panel in which a decrease in aperture ratio accompanied by fabrication of a high-definition panel is prevented.

The light-emitting panel described in this embodiment as an example and the light-emitting panel described in Embodiment 1 as an example are the same in a point that the first sub-pixel includes the first light-emitting element 420R and the second sub-pixel includes the second light-emitting element 420G, and different in the direction in which the first light-emitting element 420R and the second light-emitting element 420G are arranged with respect to the long-axis Y direction of the island-shaped first layer 423a containing the light-emitting organic compound. In addition, the light-emitting panel described in this embodiment is different in having the top-emission structure in which lights are extracted from the side opposite to the substrate 410 side on which the light-emitting elements are formed.

Specifically, in the light-emitting panel 400A described in Embodiment 1 as an example, the first light-emitting element 420R and the second light-emitting element 420G are aligned in the short-axis direction of the island-shaped first layer 423a containing the light-emitting organic compound. In contrast, in the light-emitting panel 400B described in this embodiment as an example, the first light-emitting element 420R and the second light-emitting element 420G are aligned in the long-axis direction of the island-shaped first layer 423a containing the light-emitting organic compound.

### <Layout and Defective Portion>

The relationship between the arrangement of the first light-emitting element 420R and the second light-emitting element 420G in the long-axis Y direction of the island-shaped first layer 423a containing the light-emitting organic compound and a defective portion caused by misalignment will be described with reference to FIGS. 8A1, 8A2, 8B1, and 8B2.

A top view of a light-emitting panel in which the first light-emitting element 420R and the second light-emitting element 420G are aligned in the short-axis X direction of the island-shaped first layer 423a containing the light-emitting organic compound is illustrated in FIG. 8A1.

Further, a top view of a light-emitting panel in which the first light-emitting element 420R and the second light-emitting element 420G are aligned in the long-axis Y direction of the island-shaped first layer 423a containing the light-emitting organic compound is illustrated in FIG. 8B1.

In each of the light-emitting panels, the first layer 423a containing the light-emitting organic compound is formed in an island-shaped (also referred to as “striped-shape” or “belt-shaped”) region. Note that the island-shaped first layer 423a containing the light-emitting organic compound can be formed by an evaporation method using a shadow mask method, for example.

A space with the length d2 in the short-axis X direction for misalignment caused at the time of selectively forming the island-shaped first layer 423a containing the light-emitting organic compound is provided between the first light-emitting element 420R and the third light-emitting element 420B and between the second light-emitting element 420G and the third light-emitting element 420B.

In the light-emitting panel in which the first light-emitting element 420R and the second light-emitting element 420G are aligned in the short-axis X direction, such a space is provided between the second light-emitting element 420G and the third light-emitting element 420B and between the third light-emitting element 420B and the first light-emitting element 420R (see FIG. 8A1).

In the light-emitting panel in which the first light-emitting element 420R and the second light-emitting element 420G are aligned in the long-axis Y direction, such a space is provided between the first light-emitting element 420R and the third light-emitting element 420B and between the second light-emitting element 420G and the third light-emitting element 420B (see FIG. 8B1).

The space with the length d2 in the short-axis X direction allows for misalignment of a length d2/2 in one short-axis X direction.

However, if the misalignment exceeds the length d2/2 by E, the island-shaped first layer 423a containing the light-emitting organic compound is formed in an unintended region (see FIG. 8A2 and FIG. 8B2).

For example, in the light-emitting panel in which the first light-emitting element 420R and the second light-emitting element 420G are aligned in the short-axis X direction (see FIG. 8A2), a defective portion 420RE in which the first layer 423a containing the light-emitting organic compound is not formed may be formed in the first light-emitting element 420R.

Further for example, in the light-emitting panel in which the first light-emitting element 420R and the second light-emitting element 420G are aligned in the long-axis Y direction (see FIG. 8B2), a defective portion 420RE in which the first layer 423a containing the light-emitting organic compound is not formed may be formed in the first light-emitting element 420R, and a defective portion 420GE in which the first layer 423a containing the light-emitting organic compound is not formed may be formed in the second light-emitting element 420G.

Focusing on the first light-emitting element 420R and the second light-emitting element 420G, in the light-emitting panel in which the first light-emitting element 420R and the second light-emitting element 420G are aligned in the short-axis X direction, the defective portion 420RE is formed only in the first light-emitting element 420R, so that the proportion of the defective portion 420RE to the normal portion in first light-emitting element 420R is increased.

In the case of the light-emitting panel in which the first light-emitting element 420R and the second light-emitting element 420G are aligned in the long-axis Y direction, the defective portion is formed in each of the first light-emitting element 420R and the second light-emitting element 420G and the proportion of the defective portion to the normal portion in each of the light-emitting elements is smaller than that in the light-emitting panel in which the first light-emitting element 420R and the second light-emitting element 420G are aligned in the short-axis X direction.

The reliability of a light-emitting panel depends on an element having the lowest reliability among a plurality of light-emitting elements in the light-emitting panel because the light-emitting panel cannot be used anymore when a light-emitting element of a specific color stops emitting light.

As described above, defective portions are concentrated in the first light-emitting element 420R in the light-emitting panel in which the first light-emitting element 420R and the second light-emitting element 420G are aligned in the short-axis X direction. In this case, even if there is no defective portion in the second light-emitting element 420G the reliability of the light-emitting panel is determined by the reliability of the first light-emitting elements 420R.

Since the proportion of the defective portion 420RE to the normal portion in the first light-emitting element 420R is large, the reliability of the first light-emitting element 420R is degraded with ease.

On the other hand, in the light-emitting panel in which the first light-emitting element 420R and the second light-emitting element 420G are aligned in the long-axis Y direction, defective portions are divided up in the first light-emitting element 420R and the second light-emitting element 420G. This lowers both the reliability of the first light-emitting element 420R and the reliability of the second light-emitting element 420G but averages out the degrees of reliability thereof.

As a result, the light-emitting panel in which the first light-emitting element 420R and the second light-emitting element 420G are aligned in the long-axis Y direction can assure higher reliability than the light-emitting panel in which the first light-emitting element 420R and the second light-emitting element 420G are aligned in the short-axis X direction.

The following describes individual components constituting the light-emitting panel of one embodiment of the present invention.

### <Reflective Film>

Reflective films (a first reflective film 419R, a second reflective film 419G, and a third reflective film 419B) are layers that reflect light emitted from the corresponding light-emitting elements. The reflective films preferably have as high reflectivity with respect to visible light as possible, and are preferably silver, aluminum, an alloy containing one element selected from silver and aluminum, or the like, for example (see FIG. 2B).

Note that the reflective films having conductivity can also serve as wirings that are electrically connected to the lower electrodes (the first lower electrode 421R, the second lower electrode 421G, and the third lower electrode 421B). Alternatively, a structure in which the reflective films also serve as the lower electrodes can be employed.

As a material that can be used for the reflective films also serving as the lower electrodes, it is preferable to use a material on a surface of which a conductive oxide film is formed and/or which has an appropriate work function, in order to facilitate carrier injection to the layer containing a light-emitting organic compound.

As the reflective films also serving as the lower electrodes, an aluminum-nickel-lanthanum alloy or the like can be given, for example.

### <Modification Example>

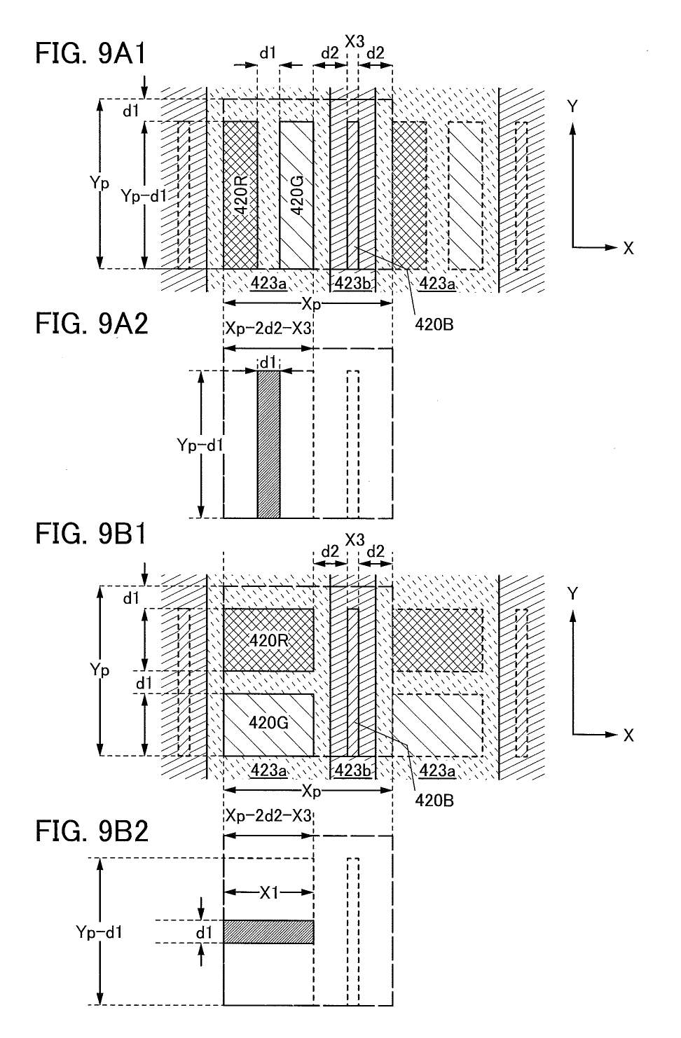

A modification example of this embodiment will be described with reference to FIG. 3 and FIGS. 9A1, 9A2, 9B1, and 9B2.

FIG. 3 is a top view of the structure of a light-emitting panel 400C of one embodiment of the present invention.

FIGS. 9A1, 9A2, 9B1, and 9B2 are top views for describing the layout of light-emitting elements in sub-pixels and a space between the light-emitting elements in a light-emitting panel of an embodiment.

In the light-emitting panel 400C described in this embodiment as an example, the sum of a length Y1 of the first light-emitting element 420R, a length Y2 of the second light-emitting element 420G, and the length d1 of the space provided between the first light-emitting element 420R and the second light-emitting element 420G in the long-axis Y direction of the island-shaped first layer 423a containing the light-emitting organic compound is larger than a length X1 of the first light-emitting element 420R or a length X2 of the second light-emitting element 420G in the short-axis X direction (see FIG. 3).

Note that the cross-sectional structure of the light-emitting panel 400C can be similar to that of the light-emitting panel 400B, and the description of the structure of the light-emitting panel 400B can be referred to here.

In the light-emitting panel 400C described in this embodiment as an example, the space with the length d1 in the long-axis Y direction of the island-shaped first layer 423a containing the light-emitting organic compound is provided between the first light-emitting element 420R and the second light-emitting element 420G. Note that the sum of the length Y1 of the first light-emitting element 420R, the length Y2 of the second light-emitting element 420G, and the length d1 of the space provided between the first light-emitting element 420R and the second light-emitting element 420G in the long-axis Y direction of the island-shaped first layer 423a containing the light-emitting organic compound is larger than the length of the first light-emitting element 420R or the second light-emitting element 420G in the short-axis X direction.

With this structure, the area of the space provided between the first light-emitting element 420R and the second light-emitting element 420G can be made small. Specifically, the area of the space can made smaller than that of the structure in which the first light-emitting element 420R and the second light-emitting element 420G are aligned in the short-axis X direction of the island-shaped first layer 423a containing the light-emitting organic compound. As a result, a novel light-emitting panel in which a decrease in aperture ratio accompanied by fabrication of a high-definition panel is suppressed can be provided.

### <Layout and Aperture Ratio>

The relationship between the layout of the first and second light-emitting elements 420R and 420G in the long-axis Y direction of the island-shaped first layer 423a containing the light-emitting organic compound and the aperture ratio will be described with reference to FIGS. 9A1, 9A2, 9B1, and 9B2.

The light-emitting panels described in the modification example of this embodiment include a plurality of pixels, each of which includes three sub-pixels (the first sub-pixel 402R, the second sub-pixel 402G, and the third sub-pixel 402B).

Each pixel has an outside shape with a length Yp in the long-axis Y direction of the island-shaped first layer 423a containing the light-emitting organic compound and a length Xp in the short-axis X direction thereof.

A light-emitting element is provided in each sup-pixel. Specifically, the first sub-pixel 402R includes the first light-emitting element 420R, the second sub-pixel 402G includes the second light-emitting element 420G, and the third sub-pixel 402B includes the third light-emitting element 420B.

Further, a space is provided between the light-emitting elements. The position of the space is similar to those illustrated in FIGS. 8A1, 8A2, 8B1, and 8B2, and the description given with reference to FIGS. 8A1, 8A2, 8B 1, and 8B2 can be referred to here.

Further, the first layer 423a containing the light-emitting organic compound is formed with an island shape (also referred to as a striped shape or a belt shape) in the light-emitting panel.

Note that in each pixel in the light-emitting panels illustrated in FIGS. 9A1, 9A2, 9B 1, and 9B2, the length Yp and the length Xp are equal.

In the light-emitting panel illustrated in FIG. 9A1, the first light-emitting element 420R and the second light-emitting element 420G are aligned in the short-axis X direction of the island-shaped first layer 423a containing the light-emitting organic compound.

In the light-emitting panel illustrated in FIG. 9B1, the first light-emitting element 420R and the second light-emitting element 420G are aligned in the long-axis Y direction of the island-shaped first layer 423a containing the light-emitting organic compound.

The first light-emitting element 420R and the second light-emitting element 420G have the same island-shaped first layer 423a containing the light-emitting organic compound between their respective pairs of electrodes. Accordingly, it is not necessary to provide, between the first light-emitting element 420R and the second light-emitting element 420G, a space for misalignment that is caused at the time of selectively forming the layer containing the light-emitting organic compound.

While in the third light-emitting element 420B, the second layer 423b containing the light-emitting organic compound is provided between the pair of electrodes and the island-shaped first layer 423a containing the light-emitting organic compound is not provided. Therefore, it is necessary to provide a space for misalignment that is caused at the time of selectively forming the layer containing the light-emitting organic compound. Specifically, it is necessary to provide a space with the length d2 in the short-axis X direction between the first light-emitting element 420R and the third light-emitting element 420B and between the second light-emitting element 420G and the third light-emitting element 420B.

For example, in the case of forming the lower electrodes of the first light-emitting element and the second light-emitting element by photolithography and forming the island-shaped first layer 423a containing the light-emitting organic compound by an evaporation method using a shadow mask method, the length d1 of the space provided between the first light-emitting element 420R and the second light-emitting element 420G can be smaller than the length d2 of the space provided between the first light-emitting element 420R and the third light-emitting element 420B and smaller than the length d2 of the space provided between the second light-emitting element 420G and the third light-emitting element 420B.

Further in the case of forming a plurality of third light-emitting elements 420B in the long-axis Y direction, it is not necessary to provide, between the adjacent third light-emitting elements 420B, a space for misalignment that is caused at the time of selectively forming the layer containing the light-emitting organic compound. Accordingly, the length of the third light-emitting element 420B in the long-axis Y direction becomes Yp−d1 (see FIG. 9A2 and FIG. 9B2).

Note that the length of the third light-emitting element 420B in the short-axis X direction is assumed to be X3.

By this arrangement of the third light-emitting elements 420B, the first light-emitting element 420R, the second light-emitting element 420G and the space provided between the first light-emitting element 420R and the second light-emitting element 420G is arranged in the region with a length Yp−d1 in the long-axis Y direction and a length Xp−2d2−X3 in the short-axis X direction (see FIG. 9A2 and FIG. 9B2).

Here, to increase the proportion of the area of light-emitting elements in the region (the aperture ratio), it is preferable that the proportion of the space provided between the first light-emitting element 420R and the second light-emitting element 420G in the region be as small as possible.

In the case where the first light-emitting element 420R and the second light-emitting element 420G are aligned in the short-axis X direction, the size of the space is as illustrated in FIG. 9A2. In the case where the first light-emitting element 420R and the second light-emitting element 420G are aligned in the long-axis Y direction, the size of the space is as illustrated in FIG. 9B2.

The area of the space provided between the first light-emitting element 420R and the second light-emitting element 420G in the case of the alignment in the short-axis X direction is represented by the product of (Yp−d1) and d1 (see FIG. 9A2). The area in the case of the alignment in the long-axis Y direction is represented by the product (Xp−2d2−X3) and d1 (see FIG. 9B2).

When (Xp−2d2−X3) is smaller than (Yp−d1) (i.e., when the region including the first light-emitting element 420R, the second light-emitting element 420G, and the space provided therebetween is long in the long-axis Y direction), by aligning the first light-emitting element 420R and the second light-emitting element 420G in the long-axis Y direction, the aperture ratio can be increased.

In particular, when Xp and Yp are equal, (Xp−2d2−X3) is always smaller than (Yp-d1); in this case, by aligning the first light-emitting element 420R and the second light-emitting element 420G in the long-axis Y direction, the aperture ratio can be increased.

Note that this embodiment can be implemented in appropriate combination with any of the other embodiments described in this specification.

### Embodiment 3

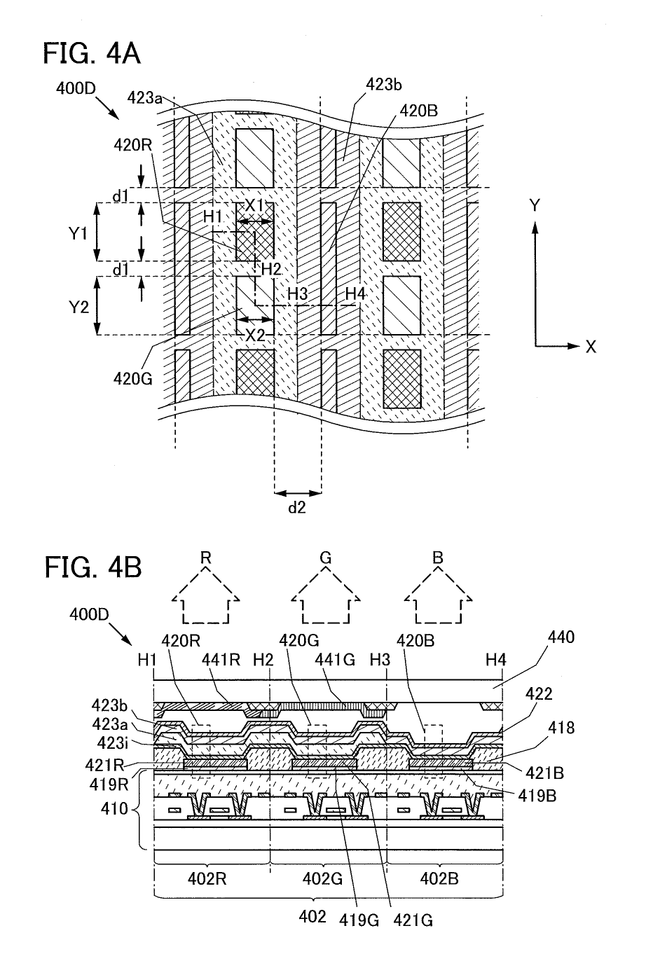

In this embodiment, a structure of a light-emitting panel of one embodiment of the present invention will be described with reference to FIGS. 4A and 4B.

FIG. 4A is a top view of the structure of the light-emitting panel of one embodiment of the present invention, and FIG. 4B is a side view of the structure of the light-emitting panel along line H1-H2-H3-H4 in FIG. 4A.

A light-emitting panel 400D described in this embodiment as an example has the structure described below in addition to the structure of the light-emitting panel 400C described in Embodiment 2 (see FIG. 4B).

The light-emitting elements (the first light-emitting element 420R, the second light-emitting element 420G, and the third light-emitting element 420B) include the second layer 423b containing the light-emitting organic compound between their respective pairs of electrodes (specifically, between the first lower electrode 421R and the upper electrode 422, between the second lower electrode 421G and the upper electrode 422, and between the third lower electrode 421B and the upper electrode 422).

The first light-emitting element 420R and the second light-emitting element 420G include the island-shaped first layer 423a containing the light-emitting organic compound between the second layer 423b containing the light-emitting organic compound and the electrode functioning as the anode of the pair of electrodes (e.g., the first lower electrode 421R, the second lower electrode 421G, and the third lower electrode 421B; or the upper electrode).

The island-shaped first layer 423a containing the light-emitting organic compound contains a plurality of light-emitting organic compounds so as to emit light with the first color and light with the second color, and the second layer containing the light-emitting organic compound contains a light-emitting organic compound that emits light with the third color.

Note that the light-emitting panel 400D is described on the assumption that the sum of the length Y1 of the first light-emitting element 4208, the length Y2 of the second light-emitting element 420G, and the length d1 of the space provided between the first light-emitting element 420R and the second light-emitting element 420G in the long-axis Y direction of the island-shaped first layer 423a containing the light-emitting organic compound is larger than the length of the first light-emitting element 420R and larger than the length of the second light-emitting element 420G in the short-axis X direction (see FIG. 4A). However, the size of the first light-emitting element 420R and the second light-emitting element 420G is not limited to that in this assumption.

The first light-emitting element 420R, the second light-emitting element 420G, and the third light-emitting element 420B of the light-emitting panel 400D described in this embodiment as an example each include the second layer 423b containing the light-emitting organic compound between their respective pairs of electrodes. Note that the second layer 423b containing the light-emitting organic compound is a continuous layer.

In the case where only the first layer 423a containing the light-emitting organic compound is formed in an island shape in this manner, the step of selectively forming the layer containing the light-emitting organic compound is required only once. This enables a reduction of the space for misalignment that is caused at the time of selectively forming the layer containing the light-emitting organic compound. Accordingly, a novel light-emitting panel in which a decrease in aperture ratio accompanied by fabrication of a high-definition panel is suppressed can be provided. Furthermore, a novel light-emitting panel which can be produced easily can be provided.

Each of the first light-emitting element 420R and the second light-emitting element 420G includes the island-shaped first layer 423a containing the light-emitting organic compound between the second layer 423b containing the light-emitting organic compound and the electrode functioning as the anode of the pair of electrodes (e.g., the lower electrode).

With this structure, holes injected from the electrode functioning as the anode (e.g., the lower electrode) and electrons injected from the electrode functioning as a cathode (e.g., the upper electrode 422) can be recombined in the island-shaped first layer 423a containing the light-emitting organic compound. This enables suppression of light emission from the second layer 423b containing the light-emitting organic compound in the first light-emitting element 420R and the second light-emitting element 420G, leading to light emission from the island-shaped first layer 423a containing the light-emitting organic compound. In addition, light emission from the second layer 423b containing the light-emitting organic compound can be obtained in the third light-emitting element 420B in which the island-shaped first layer 423a containing the light-emitting organic compound is not provided.

The island-shaped first layer 423a containing the light-emitting organic compound contains a plurality of light-emitting organic compounds so as to emit light with a first color (e.g., red) and light with a second color (e.g., green). The second layer 423b containing the light-emitting organic compound contains a light-emitting organic compound that emits light with a third color (e.g., blue).

Consequently, it is possible to provide a novel light-emitting panel in which the first sub-pixel 402R emits light with the first color (e.g., red), the second sub-pixel 402G emits light with the second color (e.g., green), and the third sub-pixel 402B emits light with the third color (e.g., blue).

### Modification Example

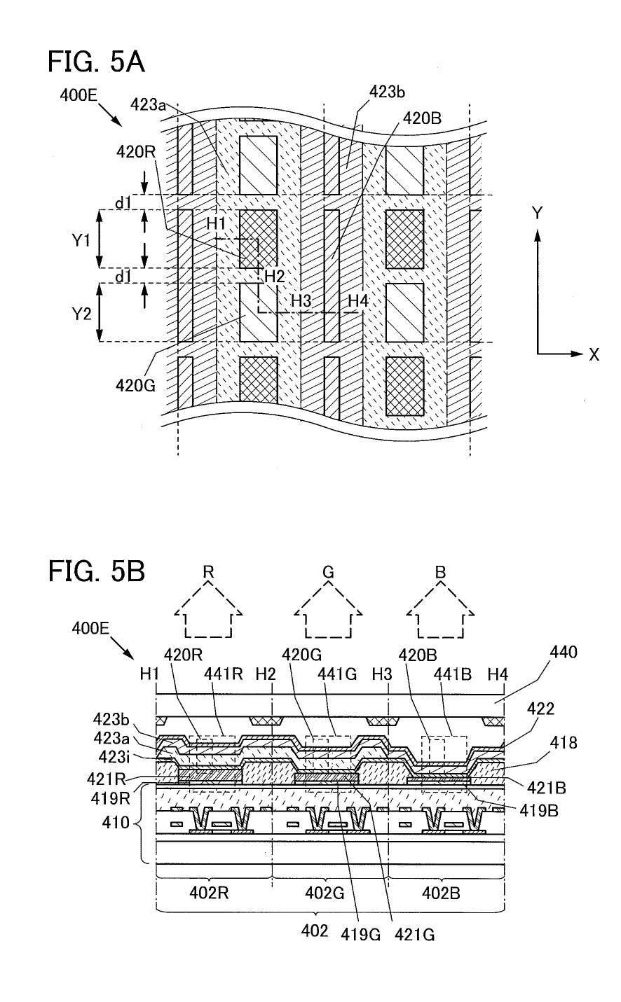

A modification example of this embodiment will be described with reference to FIGS. 5A and 5B. FIG. 5A is a top view of the structure of a light-emitting panel 400E of one embodiment of the present invention. FIG. 5B is a side view of the structure of the light-emitting panel 400E along line H1-H2-H3-H4 in FIG. 5A.

Note that the light-emitting panel 400E has the same structure as the light-emitting panel 400D except the structure of the optical elements. Therefore, the above description can be referred to for the same structure in this modification example, and the structure of the optical elements is mainly described here.

The light-emitting panel 400E described in this embodiment as an example includes optical elements employing the microcavity structure.

The microcavity structure uses a reflective film and a semitransparent/semireflective film. An optical distance adjustment layer and a light-emitting element are arranged between the reflective film and the semitransparent/semireflective film, and the optical distance between the reflective film and the semitransparent/semireflective film is adjusted so that light of a specific wavelength is strengthened.

By combining the microcavity structure with a light-emitting element, light of a specific wavelength can be efficiently extracted from light emitted from the light-emitting element. Note that in the case of forming the reflective film and/or the semitransparent/semireflective film using a conductive film, these films can also serve as wirings or electrodes.

The light-emitting elements (the first light-emitting element 420R, the second light-emitting element 420G, and the third light-emitting element 420B) includes the second layer 423b containing the light-emitting organic compound between the respective pairs of electrodes (specifically, between the first lower electrode 421R and the upper electrode 422, between the second lower electrode 421G and the upper electrode 422, and between the third lower electrode 421B and the upper electrode 422)

The first light-emitting element 420R and the second light-emitting element 420G include the island-shaped first layer 423a containing the light-emitting organic compound between the second layer 423b containing the light-emitting organic compound and the electrode functioning as the anode of the pair of electrodes (e.g., the first lower electrode 421R, the second lower electrode 421G, and the third lower electrode 421B; or the upper electrode).

The island-shaped first layer 423a containing the light-emitting organic compound contains a plurality of light-emitting organic compounds so as to emit light with the first color and light with the second color, and the second layer 423b containing the light-emitting organic compound contains a light-emitting organic compound that emits light with the third color.

Further, the first optical element 441R includes the first reflective film 419R and the upper electrode 422 also serving as a semitransparent/semireflective film. The first lower electrode 421R formed of a light-transmitting conductive film and provided in contact with the first reflective film 419R also serves as an optical distance adjustment layer. The first reflective film 419R and the upper electrode 422 are provided so as to preferentially extract light with the first color from the light emitted from the island-shaped first layer 423a containing the light-emitting organic compound.

Furthermore, the second optical element 441G includes the second reflective film 419G and the upper electrode 422 also serving as a semitransparent/semireflective film. The second lower electrode 421G formed of a light-transmitting conductive film and provided in contact with the second reflective film 419G also serves as an optical distance adjustment layer. The second reflective film 419G and the upper electrode 422 are provided so as to preferentially extract light with the second color from the light emitted from the island-shaped first layer 423a containing the light-emitting organic compound.

Note that the light-emitting panel 400E is described on the assumption that the sum of the length Y1 of the first light-emitting element 420R, the length Y2 of the second light-emitting element 420G, and the length d1 of the space provided between the first light-emitting element 420R and the second light-emitting element 420G in the long-axis Y direction of the island-shaped first layer 423a containing the light-emitting organic compound is larger than the length of the first light-emitting element 420R and larger than the length of the second light-emitting element 420G in the short-axis X direction (see FIG. 5A). However, the size of the first light-emitting element 420R and the second light-emitting element 420G is not limited to that in this assumption.

In the third light-emitting element 420B, the second layer 423b containing the light-emitting organic compound is provided between the third lower electrode 421B and the upper electrode 422.

Further, the third optical element 441B may include the third reflective film 419B and the upper electrode 422 also serving as a semitransparent/semireflective film. The third lower electrode 421B faulted of a light-transmitting conductive film and provided in contact with the third reflective film 419B also serves as an optical distance adjustment layer. The third reflective film 419B and the upper electrode 422 are provided so as to preferentially extract light with the third color from the light emitted from the second layer 423b containing the light-emitting organic compound.

The first sub-pixel 402R of the light-emitting panel 400E described in this embodiment as an example includes the first optical element 441R that uses a microcavity with which light with the first color (e.g., red) is preferentially extracted from the light emitted from the first light-emitting element 420R. Further, the second sub-pixel 402G includes the second optical element 441G that uses a microcavity with which light with the second color (e.g., green) is preferentially extracted from the light emitted from the second light-emitting element 420G.

The third light-emitting element 420B includes the second layer 423b containing the light-emitting organic compound between the pair of electrodes and emits light with the third color (e.g., blue).

In this manner, the first sub-pixel can be used as a sub-pixel that emits light with the first color (e.g., red), the second sub-pixel can be used as a sub-pixel that emits light with the second color (e.g., green), and the third sub-pixel can be used as a sub-pixel that emits light with the third color (e.g., blue).

Note that this embodiment can be implemented in appropriate combination with any of the other embodiments described in this specification.

### Embodiment 4

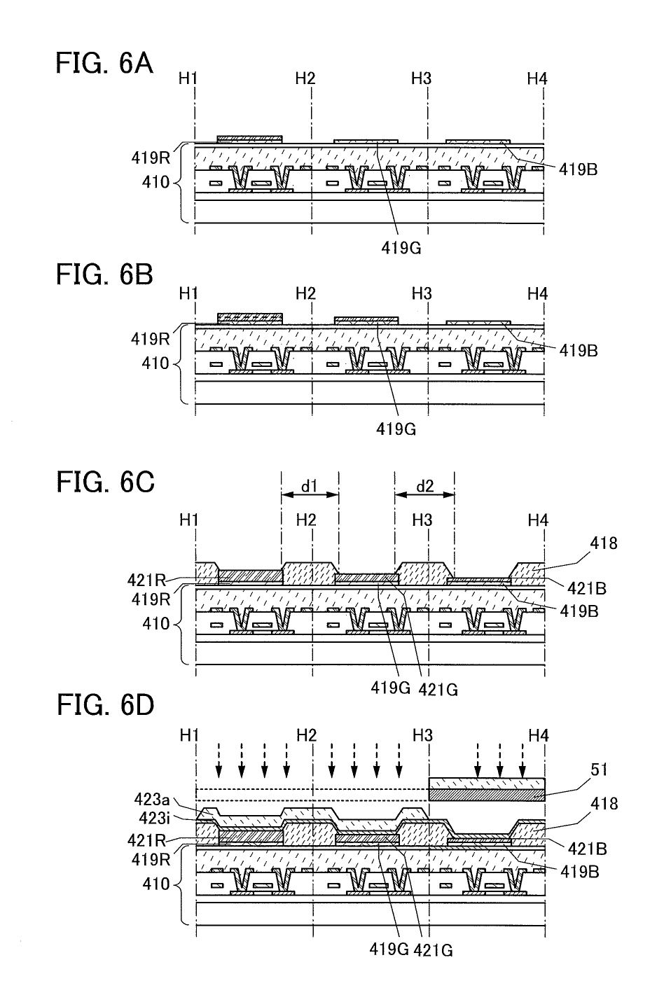

In this embodiment, a method for manufacturing a light-emitting panel of one embodiment of the present invention is described with reference to FIGS. 6A to 6D.

FIGS. 6A to 6D are side views for describing a method for manufacturing a light-emitting panel, including a cross section of one embodiment of the present invention.

The method for manufacturing a light-emitting panel described in this embodiment as an example involves the following five steps.

### <First Step>

The first step is a step of forming lower electrodes (specifically, the first lower electrode 421R, the second lower electrode 421G, and the third lower electrode 421B) of light-emitting elements over the substrate 410 on which any layer containing a light-emitting organic compound has not been formed. Since there is no possibility of damaging a layer containing a light-emitting organic compound, a variety of micromachining technologies can be employed. In this embodiment, the lower electrodes are formed by photolithography.

In the first step, reflective films (e.g., the first reflective film 419R, the second reflective film 419G, and the third reflective film 419B) are formed over the substrate 410 having an insulating surface.

Note that a transistor may be formed over the substrate 410 before the first step.

The lower electrodes serving as the optical distance adjustment layers can be formed in a plurality of steps. For example, the first lower electrode 421R also serving as the first optical distance adjustment layer can be formed in three steps, the second lower electrode 421G also serving as the second optical distance adjustment layer can be formed in two steps, and the third lower electrode 421B also serving as the third optical distance adjustment layer can be formed in one step.

Specifically, an island-shaped light-transmitting conductive film with a thickness t1 is formed only over the first reflective film 419R (see FIG. 6A). Next, an island-shaped light-transmitting conductive film with a thickness t2 is formed over the first reflective film 419R and the second reflective film 419G (see FIG. 6B). Then, an island-shaped light-transmitting conductive film with a thickness t3 is formed over the first reflective film 419R, the second reflective film 419G and the third reflective film 419B.

In this manner, an island-shaped light-transmitting conductive film with a thickness t1+t2+t3 can be formed over the first reflective film 419R. Further, an island-shaped light-transmitting conductive film with a thickness t2+t3 can be formed over the second reflective film 419G. Furthermore, an island-shaped light-transmitting conductive film with a thickness t3 can be formed over the third reflective film 419B.

Next, the insulating sidewall 418 is formed so that the insulating sidewall 418 covers edges of the island-shaped light-transmitting conductive films and opening portions of the insulating sidewall 418 overlap with the island-shaped light-transmitting conductive films (see FIG. 6C). Note that regions exposed at the opening portions of the insulating sidewall 418 function as the lower electrodes of the light-emitting elements.

Here, the second lower electrode 421G is provided apart from the first lower electrode 421R. In addition, the third lower electrode 421B is provided apart from the first lower electrode 421R and the second lower electrode 421G.

Note that the space with the length d1 is provided between the first lower electrode 421R and the second lower electrode 421G, and the space with the length d2 is provided between the first lower electrode 421R and the third lower electrode 421B and between the second lower electrode 421G and the third lower electrode 421B.

### <Second Step>

In the second step, an island-shaped first layer 423a containing the light-emitting organic compound is formed in such a manner that a shadow mask is arranged so that an opening portion of the shadow mask overlaps with the first lower electrode 421R and the second lower electrode 421G, and the first light-transmitting organic compound is evaporated from the direction in which the shadow mask is arranged.

In this embodiment, the substrate 410 is put into an evaporation apparatus, and a shadow mask 51 is arranged on the evaporation source side (not shown). Next, alignment for arranging the opening portion of the shadow mask in a desired position is performed. Specifically, the opening portion (indicated by a broken line in the drawing) of the shadow mask 51 is arranged so as to overlap with the first lower electrode 421R and the second lower electrode 421G, and the non-opening portion is arranged so as to overlap with the third lower electrode 421B (see FIG. 6D).

Note that the shadow mask 51 is a shielding plate provided with an opening portion and formed of foil of a metal or the like with a thickness of more than or equal to several tens of micrometers or a plate of a metal or the like with a thickness of less than or equal to several hundreds of micrometers.

Next, the island-shaped first layer 423a containing the light-emitting organic compound which contains an organic compound that emits light with red color and an organic compound that emits light with green color is formed by an evaporation method.

The island-shaped first layer 423a containing the light-emitting organic compound may have a stacked structure. For example, a layer containing an organic compound that emits light with red color and a layer containing an organic compound that emits light with green color may be sequentially formed to obtain a stacked structure.

The stacked structure of the island-shaped first layer 423a containing the light-emitting organic compound enables suppression of a phenomenon in which excitation energy is transferred from the excited organic compound that emits light with green color to the organic compound that emits light with red color.

The first layer 423a containing the light-emitting organic compound may be formed of only the organic compounds or a combination of the organic compounds and another material. For example, using the organic compounds as guest materials, the guest materials may be dispersed into a host material having a higher excitation energy than the guest materials.

Note that before the island-shaped first layer 423a containing the light-emitting organic compound is formed, the layer 423i containing the organic compound which is shared by the first light-emitting element 420R, the second light-emitting element 420G, and the third light-emitting element 420B may be formed over the lower electrodes.

### <Third Step>

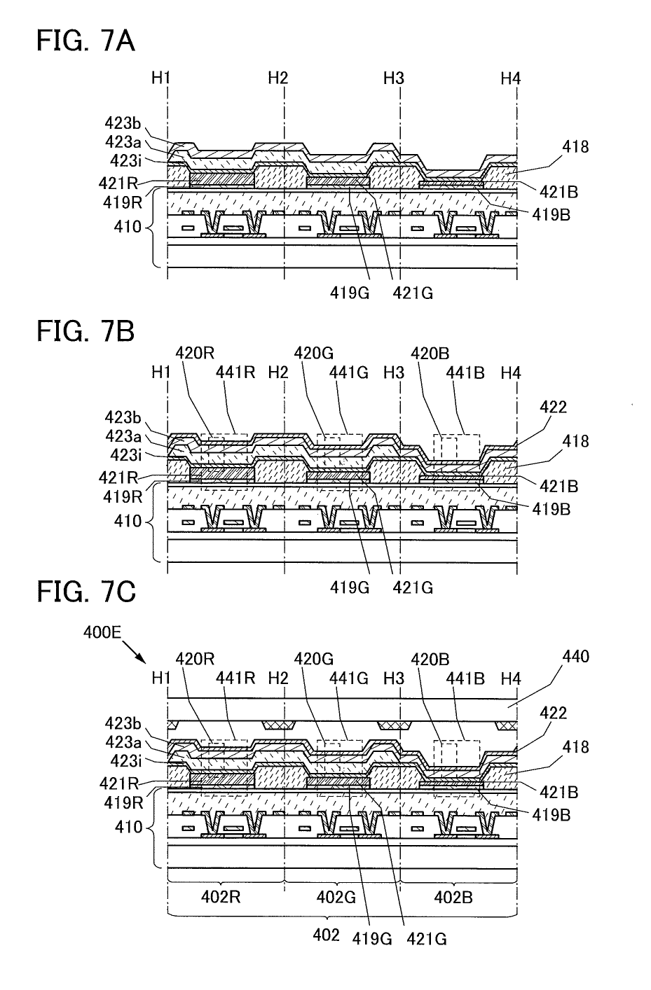

The third step is a step of forming a second layer 423b containing a light-emitting organic compound over the island-shaped first layer 423a and the third lower electrode 421B so that the second layer overlaps with the lower electrodes (the first lower electrode 421R and the second lower electrode 421G) (see FIG. 7A).

The second layer 423b containing the light-emitting organic compound which contains an organic compound that emits light with blue color is formed by an evaporation method.

The organic compound that emits light with blue color may be formed alone or formed in combination with another material. For example, using the organic compound as a guest material, the guest material may be dispersed into a host material having a higher excitation energy than the guest material.

### <Fourth Step>

The fourth step is a step of forming the upper electrode 422 also serving as a semitransparent/semireflective film over the second layer 423b so that the second layer overlaps with the lower electrodes (the first lower electrode 421R, the second lower electrode 421G, and the third lower electrode 421B).

Through this step, the first light-emitting element 420R, the second light-emitting element 420G, and the third light-emitting element 420B are formed over the substrate 410 (see FIG. 7B).

Note that by forming the upper electrode 422 also serving as a semitransparent/semireflective film overlapping with the reflective films (e.g., the first reflective film 419R, the second reflective film 419G, and the third reflective film 419B), the first optical element 441R, the second optical element 441G, and the third optical element 441B having a microcavity structure are formed.

### <Fifth Step>

The fifth step is a step of sealing the first light-emitting element 420R, the second light-emitting element 420G, and the third light-emitting element 420B between the substrate 410 and the counter substrate 440 with a sealant (not shown) (see FIG. 7C).

The sealant is provided to surround the light-emitting elements (the first light-emitting element 420R, the second light-emitting element 420G, and the third light-emitting element 420B). Then, the substrate 410 and the counter substrate 440 are bonded with the sealant so that the light-emitting elements are sealed between the counter substrate 440 and the substrate 410.

In the method for manufacturing a light-emitting panel described in this embodiment as an example, the reflective films and the optical distance adjustment layers of the optical elements and the lower electrodes of the light-emitting elements are formed before the steps of forming the island-shaped first layer containing the light-emitting organic compound and the second layer containing the light-emitting organic compound.

The step that causes damage to the layers containing light-emitting organic compounds cannot be performed after the steps of forming the layers containing light-emitting organic compounds. Since the reflective films are formed before the steps of forming the layers containing the light-emitting organic compounds, the method for forming the reflective films is not constrained by the layers containing the light-emitting organic compounds. For example, the reflective films can be faulted by photolithography before the layers containing the light-emitting organic compounds are formed. Consequently, a method for manufacturing a novel light-emitting panel in which a decrease in aperture ratio accompanied by fabrication of a high-definition panel is suppressed can be provided. Further, a novel light-emitting panel which can be produced easily can be provided.

### <Modification Example>

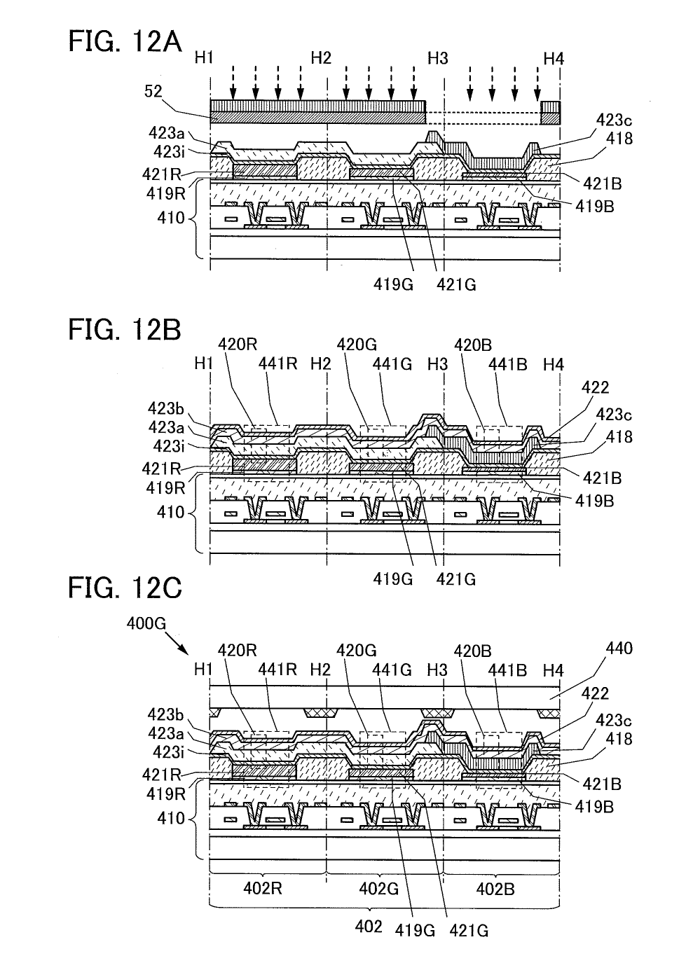

A modification example of this embodiment will be described with reference to FIGS. 12A to 12C. FIGS. 12A to 12C are side views for describing a method for manufacturing a light-emitting panel 400G, including a cross section of one embodiment of the present invention.

Note that the light-emitting panel 400G has the same structure as the light-emitting panel 400E except the structure and the manufacturing method of the light-emitting elements (the first light-emitting element 420R, the second light-emitting element 420G; and the third light-emitting element 420B).

Specifically, the light-emitting panel 400G is different in that a third layer 423c containing a light-emitting organic compound is provided over the third lower electrode 421B so as not to overlap with the first lower electrode 421R and the second lower electrode 421G, and in that the second layer 423b containing the light-emitting organic compound is formed between the first layer 423a containing the light-emitting organic compound and the upper electrode 422 and between the third layer 423c containing the light-emitting organic compound and the upper electrode 422.

Therefore, the above description can be referred to for the same structure in this modification example, and the structure and the manufacturing method of the light-emitting elements are mainly described here.

Specifically, referring to the description given with reference to FIGS. 6A to 6D, this modification example will be described with reference to FIGS. 12A to 12C.

### <Modification Example of Third Step>

A modification example of the third step is a step of selectively forming the third layer 423c containing the light-emitting organic compound over the third lower electrode 421B using a shadow mask 52, subsequent to the second step described with reference to FIG. 6C (see FIG. 12A).

Alignment for arranging the opening portion of the shadow mask in a desired position is performed. Specifically, the opening portion (indicated by a broken line in the drawing) of the shadow mask 52 is arranged so as to overlap with the third lower electrode 421B, and the non-opening portion is arranged so as to overlap with the first lower electrode 421R and the second lower electrode 421G. Next, the third layer 423c containing the light-emitting organic compound which contains an organic compound that emits light with blue color is formed by an evaporation method.

The organic compound that emits light with blue color may be formed alone or formed in combination with another material. For example, using the organic compound as a guest material, the guest material may be dispersed into a host material having a higher excitation energy than the guest material.

### <Modification Example of Fourth Step>

A modification example of the fourth step is a step of forming the second layer 423b containing the light-emitting organic compound and the upper electrode 422 also serving as a semitransparent/semireflective film in this order over the lower electrodes (the first lower electrode 421R, the second lower electrode 421G, and the third lower electrode 421B).

Through this step, the first light-emitting element 420R, the second light-emitting element 420G, and the third light-emitting element 420B are formed over the substrate 410 (see FIG. 12B).

Note that by forming the upper electrode 422 also serving as a semitransparent/semireflective film overlapping with the reflective films (e.g., the first reflective film 419R, the second reflective film 419G, and the third reflective film 419B), the first optical element 441R, the second optical element 441G, and the third optical element 441B having a microcavity structure are formed.

### <Modification Example of Fifth Step>

A modification example of the fifth step is a step of sealing the first light-emitting element 420R, the second light-emitting element 420G, and the third light-emitting element 420B between the substrate 410 and the counter substrate 440 with a sealant (not shown) (see FIG. 12C).

The sealant is provided to surround the light-emitting elements (the first light-emitting element 420R, the second light-emitting element 420G, and the third light-emitting element 420B). Then, the substrate 410 and the counter substrate 440 are bonded with the sealant so that the light-emitting elements are sealed between the counter substrate 440 and the substrate 410.

In the light-emitting panel 400G and the method for manufacturing the light-emitting panel 400G described in the modification example of this embodiment, the reflective films and the optical distance adjustment layers of the optical elements and the lower electrodes of the light-emitting elements are formed before the steps of forming the island-shaped first layer 423a containing the light-emitting organic compound, the island-shaped third layer 423c containing the light-emitting organic compound, and the second layer 423b containing the light-emitting organic compound.

The step that causes damage to the layers containing light-emitting organic compounds cannot be performed after the steps of forming the layers containing light-emitting organic compounds. Since the reflective films are formed before the steps of forming the layers containing the light-emitting organic compounds, the method for forming the reflective films is not constrained by the layers containing the light-emitting organic compounds. For example, the reflective films can be formed by photolithography before the layers containing the light-emitting organic compounds are formed. Consequently, a method for manufacturing a novel light-emitting panel in which a decrease in aperture ratio accompanied by fabrication of a high-definition panel is suppressed can be provided. Further, a novel light-emitting panel which can be produced easily can be provided.

Note that in the light-emitting panel 400G described in the modification example of this embodiment, the third light-emitting element 420B includes the selectively formed third layer 423c containing the light-emitting organic compound. This increases the range of choices of materials and facilitates an increase in the emission efficiency of the third light-emitting element 420B and a reduction in driving voltage.

Note that this embodiment can be implemented in appropriate combination with any of the other embodiments described in this specification.

### Embodiment 5

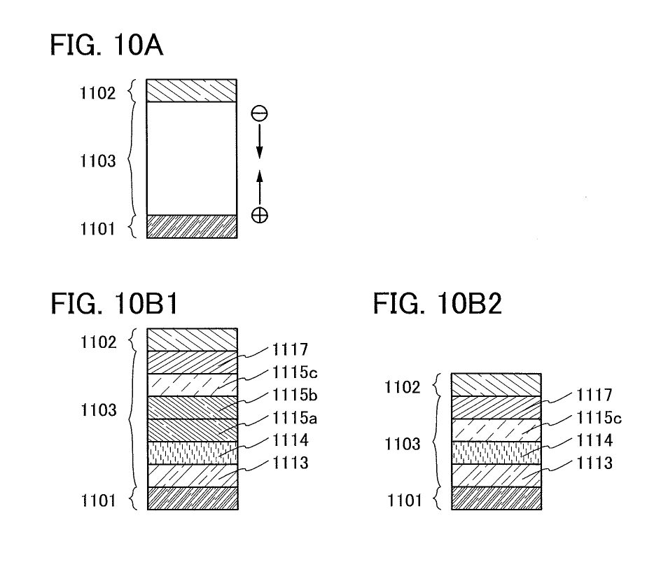

In this embodiment, the structure of a light-emitting element which can be used for the light-emitting panel according to an embodiment of the present invention will be described. Specifically, an example of a light-emitting element in which a island-shaped first layer containing a light-emitting organic compound and a second layer containing a light-emitting organic compound are sandwiched between a pair of electrodes (the first light-emitting element and the second light-emitting element) and an example of a light-emitting element in which the second layer containing the light-emitting organic compound is sandwiched between a pair of electrodes (third light-emitting element) will be described with reference to FIGS. 10A, 10B1, and 10B2.

The light-emitting element described in this embodiment as an example includes a lower electrode, an upper electrode, and a layer containing a light-emitting organic compound (hereinafter referred to as an EL layer) provided between the lower electrode and the upper electrode. One of the lower and upper electrodes functions as an anode, and the other functions as a cathode.

The EL layer is provided between the lower electrode and the upper electrode, and a structure of the EL layer may be appropriately determined in accordance with polarities and materials of the lower electrode and the upper electrode.

Examples of the structure of the light-emitting element will be described below; it is needless to say that the structure of the light-emitting element is not limited to the examples described below.

### <Structural Example of Light-Emitting Element>

An example of the structure of the light-emitting element is illustrated in FIG. 10A. In the light-emitting element illustrated in FIG. 10A, an EL layer is provided between an anode 1101 and a cathode 1102.

When voltage higher than the threshold voltage of the light-emitting element is applied between the anode 1101 and the cathode 1102, holes are injected to the EL layer from the anode 1101 side and electrons are injected to the EL layer from the cathode 1102 side. The injected electrons and holes are recombined in the EL layer, so that a light-emitting substance contained in the EL layer emits light.

In this specification, a layer or a stacked body which includes one region where electrons and holes injected from both ends are recombined is referred to as a light-emitting unit. Therefore, it can be said that Structure Example of the light-emitting element includes one light-emitting unit.

A light-emitting unit 1103 includes at least one light-emitting layer containing a light-emitting substance, and may have a structure in which the light-emitting layer and a layer other than the light-emitting layer are stacked. Examples of the layer other than the light-emitting layer are layers containing a substance having a high hole-injection property, a substance having a high hole-transport property, a substance having a poor hole-transport property (substance which blocks holes), a substance having a high electron-transport property, a substance having a high electron-injection property, and a substance having a bipolar property (substance having high electron- and hole-transport properties).

### <Structural Examples of First Light-Emitting Element and Second Light-Emitting Element>

An example of the structure of the light-emitting unit 1103 is illustrated in FIG. 10B1. In the light-emitting unit 1103 illustrated in FIG. 10B1, a hole-injection layer 1113, a hole-transport layer 1114, a first light-emitting layer 1115a, a second light-emitting layer 1115b, a third light-emitting layer 1115c, and an electron-injection layer 1117 are stacked in this order from the anode 1101 side.

Holes injected from the anode 1101 side and electrons injected from the cathode 1102 side are recombined in the vicinity of the first light-emitting layer 1115a and the second light-emitting layer 1115b, and the energy generated by the recombination causes light emission from the light-emitting organic compound.

Note that the second light-emitting layer 1115b preferably has a structure which does not transport the holes injected from the anode side to the third light-emitting layer 1115c. For example, a layer containing a material with a high electron-transport property and a low hole-transport property or a material having a deeper HOMO level than the third light-emitting layer 1115c may be provided in the second light-emitting layer 1115b so as to be in contact with the third light-emitting layer 1115c.

The first light-emitting layer 1115a contains a first light-emitting substance, and the second light-emitting layer 1115b contains a second light-emitting substance. The second light-emitting substance is selected so as to emit light with a color that is different from the color emitted from the first light-emitting substance. Accordingly, the range of emission spectrum can be widened; accordingly, the light-emitting element can emit a plurality of colors.

Combination examples of the emission colors of the first light-emitting substance and the second light-emitting substance are red and green, red and blue, green and blue, and the like.

Note that the first light-emitting element and the second light-emitting element can emit light from both the first light-emitting layer 1115a and the second light-emitting layer 1115b which emit lights of different colors. Accordingly, for efficient emission from both the first light-emitting layer 1115a and the second light-emitting layer 1115b, it is preferable that both the first light-emitting substance and the second light-emitting substance are phosphorescent substances or alternatively that both of them are fluorescent substances. In this structure, since excitons are shared between the first light-emitting layer 1115a and the second light-emitting layer 1115b, the quantum efficiency of each of the light-emitting layers is about half of the normal quantum efficiency. For this reason, it is preferable to use phosphorescent substances having high emission efficiency, and in terms of reliability, it is preferable to use green and red phosphorescent substances.

Alternatively, a structure in which light with a plurality of colors is emitted from one light-emitting layer or a structure in which light with a plurality of colors is emitted from three or more light-emitting layers may be used in addition to this structure in which lights with the plurality of colors is emitted from two light-emitting layers.

In the structural example of the light-emitting element illustrated in FIG. 10B1, the third light-emitting layer 1115c functions as not a light-emitting layer but an electron-transport layer. The third light-emitting layer 1115c transports electrons injected from the cathode 1102 side to the second light-emitting layer 1115b.

### <Structural Example of Third Light-Emitting Element>

An example of a specific structure of the light-emitting unit 1103 is illustrated in FIG. 10B2. In the light-emitting unit 1103 illustrated in FIG. 10B2, a hole-injection layer 1113, a hole-transport layer 1114, a third light-emitting layer 1115c, and an electron-injection layer 1117 are stacked in this order from the anode 1101 side.

Holes injected from the anode 1101 side and electrons injected from the cathode 1102 side are recombined in the third light-emitting layer 1115c, and the energy generated by the recombination causes light emission from the light-emitting organic compound.

The third light-emitting layer 1115c contains a third light-emitting substance. The emission color of the third light-emitting substance is different from those of the first light-emitting substance and the second light-emitting substance. In this manner, this light-emitting element emit a color that is different from the light-emitting element described with reference to FIG. 10B1.

Note that the third light-emitting layer 1115c functions as a light-emitting layer in the structural example of the light-emitting element illustrated in FIG. 10B2.

Note that in the case of using green and red phosphorescent substances in the first light-emitting layer 1115a and the second light-emitting layer 1115b, a blue light-emitting substance is preferably used in the third light-emitting layer 1115c. At this time, in terms of reliability, it is preferable to use a blue fluorescent substance. Further in the case of using a blue fluorescent substance in the third light-emitting layer 1115c, the fluorescent substance is preferably dispersed in an anthracene derivative. An anthracene derivative has a high electron-transport property. By using the anthracene derivative in the third light-emitting layer 1115c, light emission from the third light-emitting layer 1115c in the first light-emitting element and the second light-emitting element can be prevented. At this time, the fluorescent substance is preferably an aromatic amine compound because an aromatic amine compound has a high hole trapping property (a property in which holes are difficult to move) and increases an electron-transport property of the third light-emitting layer 1115c. As the aromatic amine compound, a pyrene derivative is particularly preferable.

### <Material for Light-Emitting Element>

Next, specific materials that can be used for the light-emitting element having the above-described structure are described. Materials for the anode, the cathode, and the EL layer are described in this order.

### <Material for Anode>

The anode 1101 is formed with a single-layer structure or a stacked structure using any of a metal, an alloy, an electrically conductive compound, and a mixture thereof which have conductivity. In particular, a structure in which a material with a high work function (specifically, 4.0 eV or more) is in contact with the EL layer is preferable.

Examples of the metal or the alloy material are metal materials such as gold (Au), platinum (Pt), nickel (Ni), tungsten (W), chromium (Cr), molybdenum (Mo), iron (Fe), cobalt (Co), copper (Cu), palladium (Pd), and titanium (Ti) and alloy materials thereof.

Examples of the electrically conductive compound are an oxide of a metal material, a nitride of a metal material, and an electrically conductive high molecule.

Specific examples of the oxide of a metal material are indium tin oxide (ITO), indium tin oxide containing silicon or silicon oxide, indium tin oxide containing titanium, indium titanium oxide, indium tungsten oxide, indium zinc oxide, indium zinc oxide containing tungsten, and the like. Other examples of the oxide of a metal material are molybdenum oxide, vanadium oxide, ruthenium oxide, tungsten oxide, manganese oxide, titanium oxide, and the like.

A film containing the oxide of a metal material is usually deposited by a sputtering method, but may also be formed by application of a sol-gel method or the like. For example, an indium-zinc oxide film can be formed by a sputtering method using a target in which zinc oxide is added at greater than or equal to 1 wt % and less than or equal to 20 wt % to indium oxide. A film of indium oxide containing tungsten oxide and zinc oxide can be formed by a sputtering method using a target in which tungsten oxide and zinc oxide are added at greater than or equal to 0.5 wt % and less than or equal to 5 wt % and greater than or equal to 0.1 wt % and less than or equal to 1 wt %, respectively, to indium oxide.

Specific examples of the nitride of a metal material are titanium nitride, tantalum nitride, and the like.

Specific examples of the electrically conductive high molecule are poly(3,4-ethylenedioxythiophene)/poly(styrenesulfonic acid) (PEDOT/PSS), polyaniline/poly(styrenesulfonic acid) (PAni/PSS), and the like.

Note that in the case where a second charge generation region is provided in contact with the anode 1101, a variety of electrically conductive materials can be used for the anode 1101 regardless of the magnitude of their work functions. Specifically, besides a material which has a high work function, a material which has a low work function can also be used. A material for forming the second charge generation region is described later together with a material for forming the first charge generation region.

### <Material for Cathode>

In the case where the first charge generation region is provided between the cathode 1102 and the light-emitting unit 1103 to be in contact with the cathode 1102, a variety of electrically conductive materials can be used for the cathode 1102 regardless of their work functions.

Note that at least one of the cathode 1102 and the anode 1101 is formed using an electrically conductive film that transmits visible light. For example, when one of the cathode 1102 and the anode 1101 is formed using an electrically conductive film that transmits visible light and the other is formed using an electrically conductive film that reflects visible light, a light-emitting element that emits light from one side can be formed. Alternatively, when both the cathode 1102 and the anode 1101 are formed using electrically conductive films that transmit visible light, a light-emitting element that emits light from both sides can be formed.

Examples of the electrically conductive film that transmits visible light are a film of indium tin oxide, a film of indium tin oxide containing silicon or silicon oxide, a film of indium tin oxide containing titanium, a film of indium titanium oxide, a film of indium tungsten oxide, a film of indium zinc oxide, and a film of indium zinc oxide containing tungsten. Further, a metal thin film having a thickness enough to transmit light (preferably, approximately greater than or equal to 5 nm and less than or equal to 30 nm) can also be used.

For the electrically conductive film that reflects visible light, a metal is used, for example. Specific examples thereof are metal materials such as silver, aluminum, platinum, gold, and copper, and an alloy material containing any of these. Examples of the alloy containing silver are a silver-neodymium alloy, a magnesium-silver alloy, and the like. Examples of the alloy of aluminum are an aluminum-nickel-lanthanum alloy, an aluminum-titanium alloy, an aluminum-neodymium alloy, and the like.

### <Material for EL Layer>

Specific examples of materials for the above-described layers included in the light-emitting unit 1103 are given below.

The hole-injection layer is a layer including a substance having a high hole-injection property. As the substance having a high hole-injection property, for example, molybdenum oxide, vanadium oxide, ruthenium oxide, tungsten oxide, manganese oxide, or the like can be used. In addition, it is possible to use a phthalocyanine-based compound such as phthalocyanine (abbreviation: H₂Pc) or copper phthalocyanine (abbreviation: CuPc), a high molecule such as poly(3,4-ethylenedioxythiophene)/poly(styrenesulfonic acid) (PEDOT/PSS), or the like to form the hole-injection layer.

Note that the hole-injection layer may be formed using the second charge generation region. When the second charge generation region is used for the hole-injection layer, a variety of electrically conductive materials can be used for the anode 1101 regardless of their work functions as described above. A material for forming the second charge generation region is described later together with a material for forming the first charge generation region.

### <Hole-Transport Layer>

The hole-transport layer is a layer including a substance having a high hole-transport property. The hole-transport layer is not limited to a single layer, and may be a stack of two or more layers each containing a substance having a high hole-transport property. The hole-transport layer contains a substance having a higher hole-transport property than an electron-transport property, and preferably contains a substance having a hole mobility higher than or equal to 10⁻⁶ cm²/Vs because the driving voltage of the light-emitting element can be reduced.

Examples of the substance having a high hole-transport property are aromatic amine compounds (e.g., 4,4′-bis[N-(1-naphthyl)-N-phenylamino]biphenyl (abbreviation: NPB or α-NPD), carbazole derivatives (e.g., 9-[4-(10-phenyl-9-anthracenyl)phenyl]-9H-carbazole (abbreviation: CzPA)), and the like. Alternatively, a high molecular compound (e.g., poly(N-vinylcarbazole) (abbreviation: PVK)), or the like can be used.

### <Light-Emitting Layer>

The light-emitting layer is a layer including a light-emitting substance. The light-emitting layer is not limited to a single layer, but may be a stack of two or more layers containing light-emitting substances. As the light-emitting substance, a fluorescent compound or a phosphorescent compound can be used. As the light-emitting substance, a phosphorescent compound is preferably used, in which case the emission efficiency of the light-emitting element can be increased.

As the light-emitting substance, a fluorescent compound (e.g., coumarin 545T) or a phosphorescent compound (e.g., tris(2-phenylpyridinato)iridium(III) (abbreviation: Ir(ppy)₃)) can be used.

The light-emitting substance is preferably dispersed in a host material. The host material preferably has higher excitation energy than the light-emitting substance.

As the material which can be used as the host material, the above-mentioned substance having a high hole-transport property (e.g., an aromatic amine compound, a carbazole derivative, and a high molecular compound), a substance having a high electron-transport property (e.g., a metal complex having a quinoline skeleton or a benzoquinoline skeleton and a metal complex having an oxazole-based ligand or a thiazole-based ligand), which will be described later, or the like can be used.

### <Electron-Transport Layer>

The electron-transport layer is a layer including a substance having a high electron-transport property. The electron-transport layer is not limited to a single layer, and may be a stack of two or more layers each containing a substance having a high electron-transport property. The electron-transport layer contains a substance having a higher electron-transport property than a hole-transport property, and preferably contains a substance having an electron mobility higher than or equal to 10⁻⁶ cm²/V·s, in which case the driving voltage of the light-emitting element can be reduced.

Examples of the substance having a high electron-transport property include a metal complex having a quinoline skeleton or a benzoquinoline skeleton (e.g., tris(8-quinolinolato)aluminum (abbreviation: Alq)), a metal complex having an oxazole-based or thiazole-based ligand (e.g., bis[2-(2-hydroxyphenyl)benzoxazolato]zinc (abbreviation: Zn(BOX)₂)), and other compounds (e.g., bathophenanthroline (abbreviation: BPhen)). Alternatively, a high molecular compound (e.g., poly[(9,9-dihexylfluorene-2,7-diyl)-co-(pyridine-3,5-diyl)] (abbreviation: PF-Py)) or the like can be used.

### <Electron-Injection Layer>

The electron-injection layer is a layer including a substance having a high electron-injection property. The electron-injection layer is not limited to a single layer, and may be a stack of two or more layers containing substances having a high electron-injection property. The electron-injection layer is preferably provided because the efficiency of electron injection from the cathode 1102 can be increased and the driving voltage of the light-emitting element can be reduced.

Examples of the substance having a high electron-injection property are an alkali metal (e.g., lithium (Li), or cesium (Cs)), an alkaline earth metal (e.g., calcium (Ca)), a compound of such a metal (e.g., oxide (specifically, lithium oxide, or the like), a carbonate (specifically, lithium carbonate, cesium carbonate, or the like), a halide (specifically, lithium fluoride (LiF), cesium fluoride (CsF), or calcium fluoride (CaF₂)), and the like.

Alternatively, the layer including the substance having a high electron-injection property may be a layer including a substance having a high electron-transport property and a donor substance (specifically, a layer made of Alq containing magnesium (Mg)). Note that the donor substance is preferably added so that the mass ratio of the donor substance to the substance having a high electron-transport property is greater than or equal to 0.001:1 and less than or equal to 0.1:1.

As the donor substance, an alkali metal, an alkaline earth metal, a rare earth metal, a compound of any of these metals, an organic compound such as tetrathianaphthacene (abbreviation: TTN), nickelocene, or decamethylnickelocene can be used.

### <Material for Charge Generation Region>

The first charge generation region and the second charge generation region are regions containing a substance having a high hole-transport property and an acceptor substance. The charge generation region may not only include a substance having a high hole-transport property and an acceptor substance in the same film but may include a stack of a layer including a substance having a high hole-transport property and a layer including an acceptor substance. Note that in the case where the first charge generation region provided on the cathode side has a stacked structure, the layer including the substance having a high hole-transport property is in contact with the cathode 1102. In the case where the second charge generation region provided on the anode side has a stacked structure, the layer including the acceptor substance is in contact with the anode 1101.

Note that the acceptor substance is preferably added to the charge generation region so that the mass ratio of the acceptor substance to the substance having a high hole-transport property is greater than or equal to 0.1:1 and less than or equal to 4.0:1.

Examples of the acceptor substance that is used for the charge generation region are a transition metal oxide and an oxide of a metal belonging to Group 4 to Group 8 of the periodic table. Specifically, molybdenum oxide is particularly preferable. Note that molybdenum oxide has a low hygroscopic property.

As the substance having a high hole-transport property used for the charge generation region, any of a variety of organic compounds such as an aromatic amine compound, a carbazole derivative, an aromatic hydrocarbon, and a high molecular compound (e.g., an oligomer, a dendrimer, or a polymer) can be used. Specifically, a substance having a hole mobility higher than or equal to 10⁻⁶ cm²/Vs is preferably used. Note that other than the above substances, any substance that has a property of transporting more holes than electrons may be used.

### <Material for Electron-Relay Layer>

The electron-relay layer is a layer that can immediately receive electrons drawn out by the acceptor substance in the first charge generation region. Hence, the electron-relay layer is a layer including a substance having a high electron-transport property. Its LUMO level is provided between the acceptor level of the acceptor substance in the first charge generation region and the LUMO level of the light-emitting unit 1103 in contact with the electron-relay layer. Specifically, the LUMO level of the electron-relay layer is preferably higher than or equal to −5.0 eV and lower than or equal to −3.0 eV.

Examples of the substance used for the electron-relay layer are a perylene derivative (e.g., 3,4,9,10-perylenetetracarboxylic dianhydride (abbreviation: PTCDA)), a nitrogen-containing condensed aromatic compound (pirazino[2,3-f][1,10]phenanthroline-2,3-dicarbonitrile (abbreviation: PPDN)), and the like.

Note that a nitrogen-containing condensed aromatic compound is preferably used for the electron-relay layer because of its stability. Among nitrogen-containing condensed aromatic compounds, a compound having an electron-withdrawing group such as a cyano group or a fluoro group is preferably used because such a compound further facilitates acceptance of electrons in the electron-relay layer.

### <Material for Electron-Injection Buffer>

An electron-injection buffer is a layer including a substance having a high electron-injection property. The electron-injection buffer is a layer that facilitates electron injection from the first charge generation region into the light-emitting unit 1103. By providing the electron-injection buffer between the first charge generation region and the light-emitting unit 1103, the injection barrier therebetween can be reduced.

Examples of the substance having a high electron-injection property are an alkali metal, an alkaline earth metal, a rare earth metal, a compound of any of these metals, and the like.

Further, the layer including a substance having a high electron-injection property may be a layer including a substance having a high electron-transport property and a donor substance.

### <Method for Manufacturing Light-Emitting Element>

One mode of a method for manufacturing a light-emitting element is described. Over the lower electrode, the layers described above are combined as appropriate to form the EL layer. Any of a variety of methods (e.g., a dry process or a wet process) can be used to form the EL layer depending on the material for the EL layer. For example, a vacuum evaporation method, a transfer method, a printing method, an inkjet method, a spin coating method, or the like may be selected. Note that different formation methods may be employed for the layers. The upper electrode is formed over the EL layer. In the above manner, the light-emitting element is manufactured.

The light-emitting element described in this embodiment can be manufactured by combination of the above-described materials. From this light-emitting element, light emitted from the above-described light-emitting substance can be obtained. The emission color can be selected by changing the kind of the light-emitting substance.

Further, in order to obtain white light emission with an excellent color rendering property, an emission spectrum that spreads throughout the entire visible light region is preferable. In this case, for example, a light-emitting element may include a layer that emits a blue color, a layer that emits a green color, and a layer that emits a red color.

Note that this embodiment can be implemented in appropriate combination with any of the other embodiments described in this specification.

### Embodiment 6

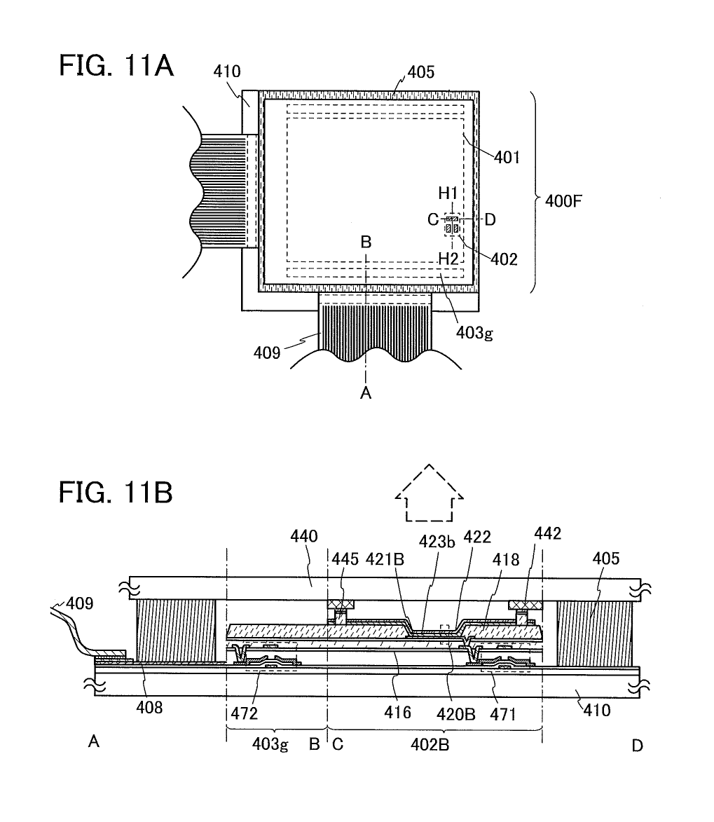

In this embodiment, a display panel to which a light-emitting panel of one embodiment of the present invention is applied will be described with reference to FIGS. 11A and 11B.

FIG. 11A is a top view of the structure of the display panel of one embodiment of the present invention, and FIG. 11B is a side view along line A-B and line C-D in FIG. 11A.

Note that a display panel 400F described in this embodiment as an example has the same top view structure and the same cross-sectional structure as the light-emitting panel 400E described with reference to FIGS. 5A and 5B in the modification example of Embodiment 3. Specifically, FIG. 5A corresponds to an enlarged view of a pixel portion illustrated in FIG. 11A, and FIG. 5B corresponds to a side view of the pixel structure including a cross section along line H1-H2-H3-H4 in FIG. 5A.

The display panel 400F described in this embodiment as an example includes a display portion 401 over the substrate 410. A plurality of pixels 402 is provided in the display portion 401. Further, a plurality of (e.g., three) sub-pixels is provided in each of the pixels 402 (FIG. 11A).

A gate driver circuit portion 403g is provided over the substrate 410. The gate driver circuit portion 403g selects a plurality of pixels provided in the display portion 401.

Note that a source driver circuit portion for supplying an image signal to the pixels selected by the gate driver circuit portion 403g may be provided over the substrate 410. Further, these driver circuit portions can be formed outside the display panel 400F.

The display panel 400F includes an external input terminal and receives a clock signal, a start signal, a reset signal, and the like from an FPC (flexible printed circuit) 409.

A printed wiring board (PWB) may be attached to the FPC 409.

Note that the display panel in this specification includes not only a main body of the display panel but one with the FPC 409 or a PWB attached thereto.

A sealant 405 bonds the substrate 410 to a counter substrate 440. The display portion 401 is sealed in a space 431 formed between the substrate 410 and the counter substrate 440 (see FIG. 11B).

The structure including the cross section of the display panel 400F will be described with reference to FIG. 11B. The display panel 400F includes the gate driver circuit portion 403g, the third sub-pixel 402B included in the pixel 402, and a lead wiring 408.

The gate driver circuit portion 403g includes an n-channel transistor 472. The transistor 472 described in this embodiment as an example is bottom-gate type, but may be top-gate type. A semiconductor layer of the transistor may be a layer of an oxide semiconductor including indium and/or zinc as well as a semiconductor layer including a Group 4 element such as silicon.

Note that the driver circuit is not limited to this structure and may be various circuits, such as a CMOS circuit, a PMOS circuit, or an NMOS circuit.

The lead wiring 408 transmits a signal input from the external input terminal to the gate driver circuit portion 403g.

Note that an insulating layer 416 and the sidewall 418 are formed over the transistor 471 and the like. The insulating layer 416 is a layer having insulating properties for planarizing a step due to the structure of the transistor 471 and the like or for suppressing impurity diffusion into the transistor 471 and the like. The insulating layer 416 may be a single layer or a stacked body including a plurality of layers. The sidewall 418 is an insulating layer having an opening portion; the third light-emitting element 420B is formed in the opening portion of the sidewall 418.

The sub-pixel 402B includes an optical element which includes the third lower electrode 421B also serving as a reflective film and the upper electrode 422 also serving as a semitransparent/semireflective film, and the third light-emitting element 420B which includes the third lower electrode 421B, the upper electrode 422, and the second layer 423b containing the light-emitting organic compound sandwiched therebetween.

Further, a light-blocking film 442 is formed. The light-blocking film 442 prevents a phenomenon in which the display panel 400 reflects external light and has an effect of increasing the contrast of images displayed on the display portion 401. Note that the light-blocking film 442 is formed on the counter substrate 440.

A spacer 445 for keeping the distance between the counter substrate 440 and the substrate 410 may be provided over the sidewall 418.

Note that the display portion 401 of the display panel 400F described in this embodiment as an example emits light in the direction indicated by the arrow in the drawing, thereby displaying images.

Note that this embodiment can be implemented in appropriate combination with any of the other embodiments described in this specification.

### EXPLANATION OF REFERENCE

51: shadow mask, 52: shadow mask, 400: display panel, 400A: light-emitting panel, 400B: light-emitting panel, 400C: light-emitting panel, 400D: light-emitting panel, 400E: light-emitting panel, 400F: display panel, 400G: light-emitting panel, 401: display portion, 402: pixel, 402B: sub-pixel, 402G: sub-pixel, 402R: sub-pixel, 403g: gate driver circuit portion, 405: sealant, 408: wiring, 409: FPC, 410: substrate, 416: insulating layer, 418: sidewall, 419B: reflective film, 419G: reflective film, 419R: reflective film, 420: light-emitting element, 420B: light-emitting element, 420G: light-emitting element, 420GE: defective portion, 420R: light-emitting element, 420RE: defective portion, 421B: lower electrode, 421G: lower electrode, 421R: lower electrode, 422: upper electrode, 423a: first layer containing a light-emitting organic compound, 423b: second layer containing a light-emitting organic compound, 423c: third layer containing a light-emitting organic compound, 423i: layer containing an organic compound, 431: space, 440: counter substrate, 441B: optical element, 441G: optical element, 441R: optical element, 442: film, 445: spacer, 471: transistor, 472: transistor, 1101: anode, 1102: cathode, 1103: light-emitting unit, 1113: hole-injection layer, 1114: hole-transport layer, 1115a: light-emitting layer, 1115b: light-emitting layer, 1115c: light-emitting layer, 1117: electron-injection layer.

This application is based on Japanese Patent Application serial no. 2012-238679 filed with Japan Patent Office on Oct. 30, 2012, the entire contents of which are hereby incorporated by reference.

1. A light-emitting device comprising:
a pixel comprising:
a first sub-pixel configured to emit a first light;
a second sub-pixel configured to emit a second light; and
a third sub-pixel configured to emit a third light,
wherein the first sub-pixel comprises:
a first light-emitting element comprising a first light-emitting layer; and
a first optical element overlapping with the first light-emitting element,
wherein the second sub-pixel comprises:
a second light-emitting element comprising the first light-emitting layer; and
a second optical element overlapping with the second light-emitting element, and
wherein the third sub-pixel comprises:
a third light-emitting element comprising a second light-emitting layer.

2. The light-emitting device according to claim 1, wherein the first light-emitting layer comprises a first light-emitting compound and a second light-emitting compound.

3. The light-emitting device according to claim 2, wherein the first light-emitting compound is a first phosphorescent substance, and the second light-emitting compound is a second phosphorescent substance.

4. The light-emitting device according to claim 2, wherein the first light-emitting compound is a first fluorescent substance, and the second light-emitting compound is a second fluorescent substance.

5. The light-emitting device according to claim 1, wherein the first optical element and the second optical element are each selected from a color filter, a band pass filter, and a multilayer filter.

6. A light-emitting device comprising:
a pixel comprising:
a first sub-pixel configured to emit a first light;
a second sub-pixel configured to emit a second light; and
a third sub-pixel configured to emit a third light,
wherein the first sub-pixel comprises;
a first light-emitting element comprising a first light-emitting layer and a second light-emitting layer; and
a first optical element overlapping with the first light-emitting element,
wherein the second sub-pixel comprises;
a second light-emitting element comprising the first light-emitting layer and the second light-emitting layer; and
a second optical element overlapping with the second light-emitting element, and
wherein the third sub-pixel comprises;
a third light-emitting element comprising the second light-emitting layer.

7. The light-emitting device according to claim 6, wherein the first light-emitting layer comprises a first light-emitting compound and a second light-emitting compound.

8. The light-emitting device according to claim 7, wherein the first light-emitting compound is a first phosphorescent substance, and the second light-emitting compound is a second phosphorescent substance.

9. The light-emitting device according to claim 7, wherein the first light-emitting compound is a first fluorescent substance, and the second light-emitting compound is a second fluorescent substance.

10. The light-emitting device according to claim 6, wherein the first optical element and the second optical element are each selected from a color filter, a band pass filter, and a multilayer filter.

11. A method for manufacturing a light-emitting device comprising:
forming a first electrode, a second electrode, and a third electrode over an insulating surface.
forming a first light-emitting layer over the first electrode and the second electrode,
forming a second light-emitting layer over the first light-emitting layer and the third electrode, and
forming a fourth electrode over the second light-emitting layer.

12. The method according to claim 11, further comprising a step of forming a first optical element and a second optical element over the insulating surface, before forming the first electrode, the second electrode, and the third electrode, so that the first electrode and the second electrode are formed over the first optical element and the second optical element, respectively.

13. The method according to claim 12, wherein the first optical element and the second optical element are each selected from a color filter, a band pass filter, and a multilayer filter.

14. The method according to claim 11, further comprising a step of forming a first optical element and a second optical element over the fourth electrode so as to overlap with the first electrode and the second electrode, respectively.

15. The method according to claim 14, wherein the first optical element and the second optical element are each selected from a color filter, a band pass filter, and a multilayer filter.

16. The method according to claim 11, wherein the first light-emitting layer comprises a first light-emitting compound and a second light-emitting compound.

17. The method according to claim 16, wherein the first light-emitting compound is a first phosphorescent substance, and the second light-emitting compound is a second phosphorescent substance.

18. The method according to claim 16, wherein the first light-emitting compound is a first fluorescent substance, and the second light-emitting compound is a second fluorescent substance.
